(19) United States
(12) Patent Application Publication
(10) Pub. No.: US 2024/0215447 A1
(43) Pub. Date: Jun. 27, 2024

(54) ORGANIC ELECTROLUMINESCENT ELEMENT AND ELECTRONIC DEVICE

(71) Applicants: IDEMITSU KOSAN CO.,LTD., Chiyoda-ku, Tokyo (JP); TORAY INDUSTRIES, INC., Chuo-ku, Tokyo (JP)

(72) Inventors: Hiromi NAKANO, Chiyoda-ku (JP); Hisato MATSUMOTO, Chiyoda-ku (JP); Takushi SHIOMI, Chiyoda-ku (JP); Toshinari OGIWARA, Chiyoda-ku (JP); Keiichi YASUKAWA, Chiyoda-ku (JP); Kazunari KAWAMOTO, Otsu-shi (JP); Takashi TOKUDA, Otsu-shi (JP); Kazumasa NAGAO, Otsu-shi (JP)

(73) Assignees: IDEMITSU KOSAN CO.,LTD., Chiyoda-ku, Tokyo (JP); TORAY INDUSTRIES, INC., Chuo-ku, Tokyo (JP)

(21) Appl. No.: 18/546,535

(22) PCT Filed: Feb. 16, 2022
(86) PCT No.: PCT/JP2022/006217

§ 371 Date: Aug. 15, 2023

(30) Foreign Application Priority Data
Feb. 19, 2021 (JP) 2021-025488

(51) Int. Cl. H10K 85/60; C09K 11/06

(52) U.S. Cl. CPC H10K 85/658; C09K 11/06; H10K 85/657; H10K 85/6572; H10K 85/6574; H10K 50/12

(57) ABSTRACT

An organic electroluminescence device may include an emitting layer between an anode and a cathode, in which the emitting layer contains a first compound that fluoresces, a second compound that exhibits delayed fluorescence, and a third compound. The first compound may have formula (1):

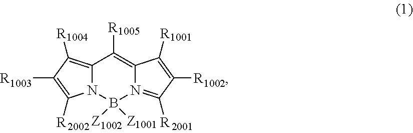

the second compound may have formula (2):

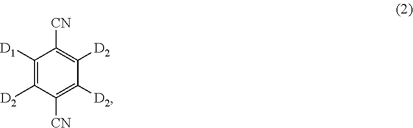

the third compound may have formula (3):

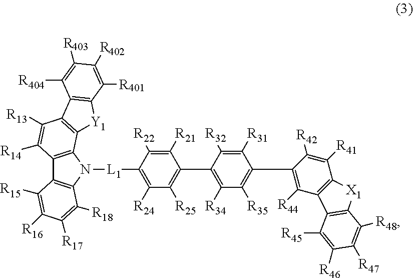

, and
   a singlet energy of the first compound S₁(M1), a singlet energy of the second compound S₁(M2), and a singlet energy of the third compound S₁(M3) satisfy a Inequality

S₁(M3)>S₁(M2)>S₁(M1) (Eq. 1).

### TECHNICAL FIELD

The present invention relates to an organic electroluminescence device and an electronic device.

### BACKGROUND ART

When voltage is applied to an organic electroluminescence device (hereinafter, occasionally referred to as “organic EL device”), holes are injected from an anode and electrons are injected from a cathode into an emitting layer. The injected electrons and holes are recombined in the emitting layer to form excitons. Specifically, according to the electron spin statistics theory, singlet excitons and triplet excitons are generated at a ratio of 25%:75%.

A fluorescent organic EL device using light emission from singlet excitons has been applied to a full-color display such as a mobile phone and a television, but an internal quantum efficiency is said to be at a limit of 25%. Studies have thus been made to improve performance of the organic EL device.

Further, the organic EL device is expected to emit light more efficiently using triplet excitons in addition to singlet excitons. In view of the above, a highly-efficient fluorescent organic EL device using thermally activated delayed fluorescence (hereinafter simply referred to as “delayed fluorescence” in some cases) has been proposed and studied.

For instance, a thermally activated delayed fluorescence (TADF) mechanism has been studied. This TADF mechanism uses a phenomenon in which inverse intersystem crossing from triplet excitons to singlet excitons thermally occurs when a material having a small energy difference (ΔST) between singlet energy level and triplet energy level is used. Thermally activated delayed fluorescence is explained in “Yuki Hando-tai no Debaisu Bussei (Device Physics of Organic Semiconductors)” (edited by ADACHI Chihaya, published by Kodansha, issued on Apr. 1, 2012, on pages 261-268).

For instance, Patent Literatures 1 and 2 each describe a compound used for an organic electroluminescence device using the TADF mechanism. For instance, Patent Literature 3 describes a pyrromethene metal complex used together with a compound exhibiting thermally activated delayed fluorescence (hereinafter also referred to as a thermally activated delayed fluorescent compound) in an emitting layer.

### CITATION LIST

### Patent Literature(s)

Patent Literature 1 International Publication No. WO 2020/022378

Patent Literature 2 International Publication No. WO 2020/122118

Patent Literature 3 International Publication No. WO 2020/184369

### SUMMARY OF THE INVENTION

### Problem(s) to be Solved by the Invention

The organic EL device using the TADF mechanism is in need of further performance improvement.

An object of the invention is to provide an organic electroluminescence device and an electronic device excellent in performance.

### Means for Solving the Problem(s)

According to an aspect of the invention, there is provided an organic electroluminescence device including: an anode; a cathode; and an emitting layer between the anode and the cathode, in which the emitting layer contains a first compound that fluoresces, a second compound that exhibits delayed fluorescence, and a third compound, the first compound is represented by a formula (1) below, the second compound is represented by a formula (2) below, the third compound is represented by a formula (3) below, and a singlet energy of the first compound S₁(M1), a singlet energy of the second compound S₁(M2), and a singlet energy of the third compound S₁(M3) satisfy a relationship of a numerical formula (Numerical Formula 1) below.

S₁(M3)>S₁(M2)>S₁(M1) (Numerical Formula 1)

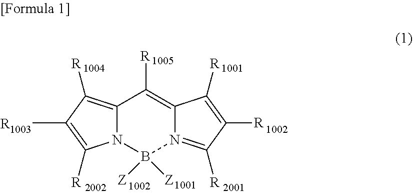

In the formula (1):
R₁₀₀₁ to R₁₀₀₅ and R₂₀₀₁ to R₂₀₀₂ are each independently a hydrogen atom or a substituent, or at least one combination of a combination of R₁₀₀₁ and R₁₀₀₂, a combination of R₁₀₀₂ and R_{2001,} a combination of R₂₀₀₂ and R₁₀₀₃, or a combination of R₁₀₀₃ and R₁₀₀₄ are mutually bonded to form a ring;
R₁₀₀₁ to R₁₀₀₅ and R₂₀₀₁ to R₂₀₀₂ as the substituents are each independently selected from the group consisting of a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted cycloalkenyl group having 3 to 30 ring carbon atoms, a substituted or unsubstituted alkynyl group having 2 to 30 carbon atoms, a substituted or unsubstituted heteroaryl group having 5 to 30 ring atoms, a halogen atom, a carboxy group, a formyl group, a substituted or unsubstituted acyl group, a substituted or unsubstituted ester group, a substituted or unsubstituted carbamoyl group, a substituted or unsubstituted amino group, a hydroxy group, a thiol group, a nitro group, a cyano group, a substituted or unsubstituted silyl group, and a substituted or unsubstituted siloxanyl group; and
Z₁₀₀₁ and Z₁₀₀₂ are each independently selected from the group consisting of a halogen atom, a cyano group, a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, and a substituted or unsubstituted aryloxy group having 6 to 30 ring carbon atoms.

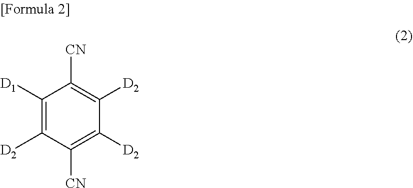

In the formula (2): CN is a cyano group, D₁ is a group represented by a formula (2-1) below, D₂ is a group represented by a formula (2-2) below, and a plurality of D₂ are mutually the same group.

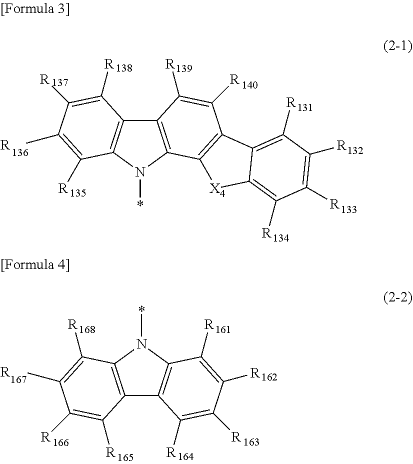

In the formulae (2-1):
X₄ is a sulfur atom;
R₁₃₁ to R₁₄₀ are each independently a hydrogen atom or a substituent;
R₁₃₁ to R₁₄₀ as the substituents are each independently a substituted or unsubstituted aryl group having 6 to 14 ring carbon atoms, a substituted or unsubstituted heterocyclic group having 5 to 14 ring atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms; and
* represents a bonding position to a benzene ring in the formula (2).
   In the formulae (2-2):
R₁₆₁ to R₁₆₈ are each independently a hydrogen atom or a substituent;
R₁₆₁ to R₁₆₈ as the substituents are each independently a halogen atom, a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted cycloalkyl group having 3 to 30 ring carbon atoms, a substituted or unsubstituted alkyl halide group having 1 to 30 carbon atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms; and
each * independently represents a bonding position to a benzene ring in the formula (2).

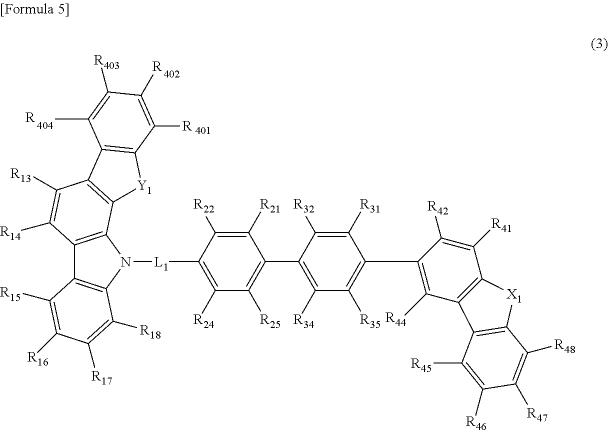

In the formula (3):
X₁ is an oxygen atom or a sulfur atom;
Y₁ is an oxygen atom or a sulfur atom;
L₁ is a single bond or a linking group;
L₁ as the linking group is a group derived from a substituted or unsubstituted aryl group having 6 to 30 ring carbon atoms, a group derived from a substituted or unsubstituted heterocyclic group having 5 to 30 ring atoms, or a group formed by bonding two groups selected from the group consisting of a group derived from a substituted or unsubstituted aryl group having 6 to 30 ring carbon atoms and a group derived from a substituted or unsubstituted heterocyclic group having 5 to 30 ring atoms;
R₄₁, R₄₂ and R₄₄ to R₄₈ are each independently a hydrogen atom or a substituent, or at least one combination of a combination of R₄₁ and R₄₂, a combination of R₄₅ and R₄₆, a combination of R₄₆ and R₄₇, or a combination of R₄₇ and R₄₈ are mutually bonded to form a ring;
R₃₁, R₃₂, R₃₄, and R₃₅ are each independently a hydrogen atom or a substituent;
R₂₁, R₂₂, R₂₄, and R₂₅ are each independently a hydrogen atom or a substituent;
R₁₃ to R₁₈ and R₄₀₁ to R₄₀₄ are each independently a hydrogen atom or a substituent, or at least one combination of a combination of R₁₃ and R₁₄, a combination of R₁₅ and R₁₆, a combination of R₁₆ and R₁₇, a combination of R₁₇ and R₁₈, a combination of R₄₀₁ and R₄₀₂, a combination of R₄₀₂ and R₄₀₃, or a combination of R₄₀₃ and R₄₀₄ are mutually bonded to form a ring; and
R₄₁, R₄₂, R₄₄ to R₄₈, R₃₁, R₃₂, R₃₄, R₃₅, R₂₁, R₂₂, R₂₄, R₂₅, R₁₃ to R₁₈, and R₄₀₁ to R₄₀₄ as the substituents are each independently a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkyl halide group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 60 ring carbon atoms, a substituted or unsubstituted aryl phosphoryl group having 6 to 60 ring carbon atoms, a hydroxy group, a substituted or unsubstituted alkoxy group having 1 to 30 carbon atoms, a substituted or unsubstituted aryloxy group having 6 to 30 ring carbon atoms, an amino group, a substituted or unsubstituted alkylamino group having 2 to 30 carbon atoms, a substituted or unsubstituted arylamino group having 6 to 60 ring carbon atoms, a thiol group, a substituted or unsubstituted alkylthio group having 1 to 30 carbon atoms, or a substituted or unsubstituted arylthio group having 6 to 30 ring carbon atoms.

According to another aspect of the invention, there is provided an electronic device including the organic electroluminescence device according to the aspect of the invention.

According to the aspects of the invention, there can be provided an organic electroluminescence device and an electronic device excellent in performance.

### BRIEF EXPLANATION OF DRAWINGS

FIG. 1 schematically depicts an exemplary arrangement of an organic EL device according to a first exemplary embodiment.

FIG. 2 schematically depicts an apparatus for measuring transient PL.

FIG. 3 illustrates an example of decay curves of the transient PL.

FIG. 4 illustrates a relationship in energy level and energy transfer between a first compound, a second compound, and a third compound in an emitting layer of an exemplary organic EL device according to the first exemplary embodiment.

### DESCRIPTION OF EMBODIMENT(S)

### First Exemplary Embodiment

An arrangement of an organic EL device according to a first exemplary embodiment of the invention will be described below.

The organic EL device includes an organic layer between an anode and a cathode. The organic layer includes a plurality of layers formed from an organic compound(s). The organic layer may further contain an inorganic compound(s). In the organic EL device of the exemplary embodiment, at least one layer included in the organic layer is an emitting layer. For instance, the organic layer may be one emitting layer, or may further include a layer(s) usable in the organic EL device. Examples of the layer usable in the organic EL device, which are not particularly limited, include at least one selected from the group consisting of a hole injecting layer, a hole transporting layer, an electron injecting layer, an electron transporting layer, and a blocking layer.

The organic layer of the organic EL device in the exemplary embodiment preferably has a layer arrangement below.
▪ electron blocking layer/emitting layer/hole blocking layer ▪ hole injecting layer/electron blocking layer/emitting layer/hole blocking layer ▪ hole transporting layer/electron blocking layer/emitting layer/hole blocking layer ▪ hole injecting layer/hole transporting layer/electron blocking layer/emitting layer/hole blocking layer ▪ electron blocking layer/emitting layer/hole blocking layer/electron injecting layer ▪ electron blocking layer/emitting layer/hole blocking layer/electron transporting layer ▪ electron blocking layer/emitting layer/hole blocking layer/electron transporting layer/electron injecting layer ▪ hole injecting layer/electron blocking layer/emitting layer/hole blocking layer/electron injecting layer ▪ hole injecting layer/electron blocking layer/emitting layer/hole blocking layer/electron transporting layer ▪ hole injecting layer/electron blocking layer/emitting layer/hole blocking layer/electron transporting layer/electron injecting layer ▪ hole transporting layer/electron blocking layer/emitting layer/hole blocking layer/electron injecting layer ▪ hole transporting layer/electron blocking layer/emitting layer/hole blocking layer/electron transporting layer ▪ hole transporting layer/electron blocking layer/emitting layer/hole blocking layer/electron transporting layer/electron injecting layer ▪ hole injecting layer/hole transporting layer/electron blocking layer/emitting layer/hole blocking layer/electron injecting layer ▪ hole injecting layer/hole transporting layer/electron blocking layer/emitting layer/hole blocking layer/electron transporting layer ▪ hole injecting layer/hole transporting layer/electron blocking layer/emitting layer/hole blocking layer/electron transporting layer/electron injecting layer

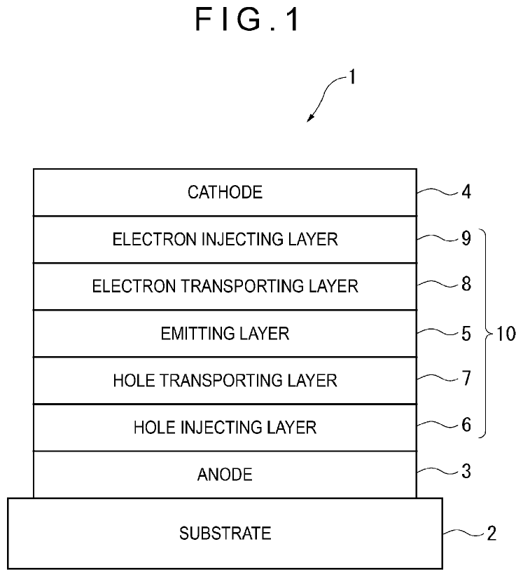

FIG. 1 schematically depicts an exemplary arrangement of an organic EL device according to the exemplary embodiment.

An organic EL device 1 includes a light-transmissive substrate 2, an anode 3, a cathode 4, and an organic layer 10 provided between the anode 3 and the cathode 4. The organic layer 10 includes a hole injecting layer 6, a hole transporting layer 7, an emitting layer 5, an electron transporting layer 8, and an electron injecting layer 9. The organic layer 10 includes the hole injecting layer 6, the hole transporting layer 7, the emitting layer 5, the electron transporting layer 8, and the electron injecting layer 9 that are layered on the anode 3 in this order.

### Emitting Layer

The emitting layer contains a first compound represented by a formula (1), a second compound represented by a formula (2), and a third compound represented by a formula (3). The first compound is a fluorescent compound and the second compound is a delayed fluorescent compound. The first compound, the second compound, and the third compound are mutually different compounds.

The first compound is also preferably a dopant material (occasionally referred to as a guest material, emitter or luminescent material). The second compound is also preferably a host material (occasionally referred to as a matrix material). The third compound is also preferably a host material (occasionally referred to as a matrix material). When the second compound and the third compound are host materials, for instance, one of the host materials may be referred to as a first host material and the other may be referred to as a second host material.

In an exemplary arrangement of the exemplary embodiment, the emitting layer may contain a metal complex. The emitting layer, however, preferably contains no phosphorescent metal complex, more preferably contains no metal complex.

In an exemplary arrangement of the exemplary embodiment, the emitting layer preferably does not contain a phosphorescent material (phosphorescent dopant material).

In an exemplary arrangement of the exemplary embodiment, the emitting layer preferably contains no heavy metal complex. Examples of the heavy metal complex herein include iridium complex, osmium complex, and platinum complex.

In an exemplary arrangement of the exemplary embodiment, the emitting layer preferably contains no phosphorescent rare-earth metal complex.

### First Compound

The first compound is a fluorescent compound. The first compound may be a delayed fluorescent compound or a compound that does not exhibit delayed fluorescence.

The first compound is represented by the formula (1) below.

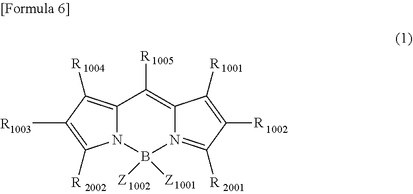

In the formula (1):
R₁₀₀₁ to R₁₀₀₅ and R₂₀₀₁ to R₂₀₀₂ are each independently a hydrogen atom or a substituent, or at least one combination of a combination of R₁₀₀₁ and R₁₀₀₂, a combination of R₁₀₀₂ and R₂₀₀₁, a combination of R₂₀₀₂ and R₁₀₀₃, or a combination of R₁₀₀₃ and R₁₀₀₄ are mutually bonded to form a ring;
R₁₀₀₁ to R₁₀₀₅ and R₂₀₀₁ to R₂₀₀₂ as the substituents are each independently selected from the group consisting of a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted cycloalkenyl group having 3 to 30 ring carbon atoms, a substituted or unsubstituted alkynyl group having 2 to 30 carbon atoms, a substituted or unsubstituted heteroaryl group having 5 to 30 ring atoms, a halogen atom, a carboxy group, a formyl group, a substituted or unsubstituted acyl group, a substituted or unsubstituted ester group, a substituted or unsubstituted carbamoyl group, a substituted or unsubstituted amino group, a hydroxy group, a thiol group, a nitro group, a cyano group, a substituted or unsubstituted silyl group, and a substituted or unsubstituted siloxanyl group; and
Z₁₀₀₁ and Z₁₀₀₂ are each independently selected from the group consisting of a halogen atom, a cyano group, a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, and a substituted or unsubstituted aryloxy group having 6 to 30 ring carbon atoms.

In the exemplary embodiment, R₂₀₀₁ and R₂₀₀₂ in the formula (1) are preferably each independently a group selected from the group consisting of a substituted or unsubstituted aryl group having 6 to 30 ring carbon atoms and a substituted or unsubstituted heteroaryl group having 5 to 30 ring atoms.

In the formula (1), also preferably, at least one combination of a combination of R₁₀₀₂ and R₂₀₀₁ or a combination of R₂₀₀₂ and R₁₀₀₃ are mutually bonded to form a ring.

In the exemplary embodiment, the compound represented by the formula (1) is preferably a compound represented by a formula (4A) or formula (4B) below.

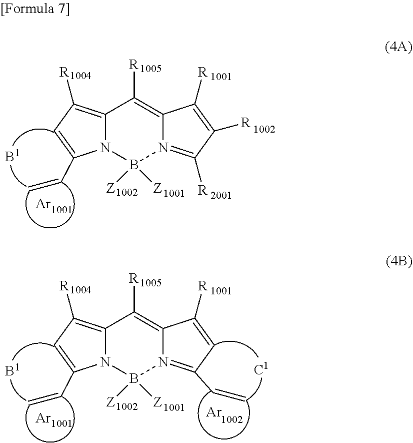

In the formula (4A), R₁₀₀₁, R₁₀₀₂, R₁₀₀₄, R₁₀₀₅, R₂₀₀₁, Z₁₀₀₁, and Z₁₀₀₂ each independently represent the same as R₁₀₀₁, R₁₀₀₂, R₁₀₀₄, R₁₀₀₅, R₂₀₀₁, Z₁₀₀₁, and Z₁₀₀₂ in the formula (1);
in the formula (4B), R₁₀₀₁, R₁₀₀₄, R₁₀₀₅, Z₁₀₀₁, and Z₁₀₀₂ each independently represent the same as R₁₀₀₁, R₁₀₀₄, R₁₀₀₅, Z₁₀₀₁ and Z₁₀₀₂ in the formula (1);
Ar₁₀₀₁ and Ar₁₀₀₂ are each independently selected from the group consisting of a substituted or unsubstituted aromatic hydrocarbon ring having 6 to 30 ring carbon atoms, and a substituted or unsubstituted aromatic heterocycle having 5 to 30 ring atoms;
B¹ is a cross-linking structure in which three or more atoms are bonded in series, the atoms being selected from the group consisting of a substituted or unsubstituted carbon atom, a substituted or unsubstituted silicon atom, a substituted or unsubstituted nitrogen atom, a substituted or unsubstituted phosphorus atom, an oxygen atom, and a sulfur atom;
C¹ is a cross-linking structure in which one or more atoms are bonded in series, the atoms being selected from the group consisting of a substituted or unsubstituted carbon atom, a substituted or unsubstituted silicon atom, a substituted or unsubstituted nitrogen atom, a substituted or unsubstituted phosphorus atom, an oxygen atom, and a sulfur atom; and
when B¹ is a trimethylene group, R₁₀₀₄ is neither a hydrogen atom nor a halogen atom.

In the formulae (4A) and (4B), a double bond shown as a part of Ar₁₀₀₁ shows a part of an aromatic hydrocarbon ring or an aromatic heterocycle, showing that a carbon atom directly bonded to a pyrromethene skeleton is adjacent to a carbon atom bonded to the cross-linking structure B¹.

Similarly, in the formula (4B), a double bond shown as a part of Ar₁₀₀₂ shows a part of an aromatic hydrocarbon ring or an aromatic heterocycle, showing that a carbon atom directly bonded to a pyrromethene skeleton is adjacent to a carbon atom bonded to the cross-linking structure C¹.

In the exemplary embodiment, R₁₀₀₁ and R₁₀₀₄ in the formulae (1), (4A), and (4B) are preferably each independently selected from the group consisting of a hydrogen atom, a substituted or unsubstituted alkyl group having 1 to 30 carbon atoms, a substituted or unsubstituted cycloalkyl group having 3 to 30 ring carbon atoms, a substituted or unsubstituted aryl group having 6 to 30 ring carbon atoms, and a substituted or unsubstituted heteroaryl group having 5 to 30 ring atoms, more preferably a substituted or unsubstituted aryl group having 6 to 30 ring carbon atoms.

In the exemplary embodiment, R₁₀₀₂ and R₁₀₀₃ in the formulae (1), (4A), and (4B) are preferably each independently selected from the group consisting of a hydrogen atom, a substituted or unsubstituted alkyl group having 1 to 30 carbon atoms, a substituted or unsubstituted cycloalkyl group having 3 to 30 ring carbon atoms, a substituted or unsubstituted aryl group having 6 to 30 ring carbon atoms, and a substituted or unsubstituted heteroaryl group having 5 to 30 ring atoms, or at least one combination of a combination of R₁₀₀₂ and R₂₀₀₁ or a combination of R₂₀₀₂ and R₁₀₀₃ are mutually bonded to form a ring.

In the exemplary embodiment, R₁₀₀₅ in the formulae (1), (4A), and (4B) are preferably selected from the group consisting of a hydrogen atom, a substituted or unsubstituted alkyl group having 1 to 30 carbon atoms, a substituted or unsubstituted cycloalkyl group having 3 to 30 ring carbon atoms, a substituted or unsubstituted aryl group having 6 to 30 ring carbon atoms, and a substituted or unsubstituted heteroaryl group having 5 to 30 ring atoms, more preferably a substituted or unsubstituted aryl group having 6 to 30 ring carbon atoms.

In the exemplary embodiment, R₂₀₀₁ and R₂₀₀₂ in the formulae (1), (4A), and (4B) are preferably each independently selected from the group consisting of a substituted or unsubstituted aryl group having 6 to 30 ring carbon atoms and a substituted or unsubstituted heteroaryl group having 5 to 30 ring atoms, more preferably a substituted or unsubstituted aryl group having 6 to 30 ring carbon atoms.

In the exemplary embodiment, Z₁₀₀₁ and Z₁₀₀₂ in the formulae (1), (4A), and (4B) are preferably each independently selected from the group consisting of a halogen atom, a cyano group, a substituted or unsubstituted alkyl halide group having 1 to 30 carbon atoms, and a substituted or unsubstituted alkoxy halide group having 1 to 30 carbon atoms, more preferably a fluorine atom.

In the exemplary embodiment, Ar₁₀₀₁ and Ar₁₀₀₂ in the formulae (4A) and (4B) are preferably each independently a substituted or unsubstituted aromatic hydrocarbon ring having 6 to 30 ring carbon atoms.

In the exemplary embodiment, B¹ in the formulae (4A) and (4B) is a cross-linking structure in which three or more atoms are bonded in series, the atoms being preferably selected from the group consisting of a substituted or unsubstituted carbon atom and an oxygen atom.

In the exemplary embodiment, C¹ in the formulae (4A) and (4B) is a cross-linking structure in which one or more atoms are bonded in series, the atoms being preferably selected from the group consisting of a substituted or unsubstituted carbon atom, a substituted or unsubstituted nitrogen atom, an oxygen atom, and a sulfur atom, more preferably selected from the group consisting of one to three substituted or unsubstituted carbon atoms for the purpose of controlling the emission peak wavelength. C¹ is still more preferably three substituted or unsubstituted carbon atoms, because molecular designing has more flexibility to meet the demand for a variety of emission peak wavelengths. C¹ is still further more preferably one or two substituted or unsubstituted carbon atoms, yet still further more preferably one substituted or unsubstituted carbon atom to narrow a full width at half maximum of emission spectrum and consequently improves chromatic purity.

In the exemplary embodiment, B¹ in the formula (4A) or (4B) is preferably a cross-linking structure represented by a formula (5A) or formula (5B) below.

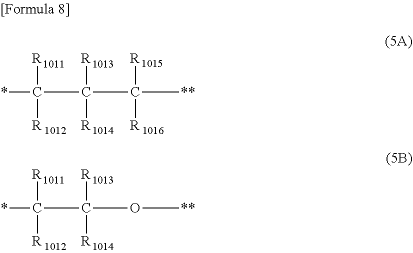

In the formula (5A), R₁₀₀₁ to R₁₀₁₆ are each independently a hydrogen atom or a substituent, or at least one combination of combinations of adjacent two or more of R₁₀₁₁ to R₁₀₁₆ are mutually bonded to form a ring;
in the formula (5B), R₁₀₁₁ to R₁₀₁₄ are each independently a hydrogen atom or a substituent, or at least one combination of combinations of adjacent two or more of R₁₀₁₁ to R₁₀₁₄ are mutually bonded to form a ring;
R₁₀₁₁ to R₁₀₁₆ as the substituents are each independently selected from the group consisting of a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted heteroaryl group having 5 to 30 ring atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted cycloalkenyl group having 3 to 30 ring carbon atoms, a substituted or unsubstituted alkynyl group having 2 to 30 carbon atoms, a halogen atom, a carboxy group, a formyl group, a substituted or unsubstituted acyl group, a substituted or unsubstituted ester group, a substituted or unsubstituted carbamoyl group, a substituted or unsubstituted amino group, a hydroxy group, a thiol group, a nitro group, a cyano group, a substituted or unsubstituted silyl group, and a substituted or unsubstituted siloxanyl group; and
* represents a bonding site to a pyrrole ring and ** represents a bonding site to Ar₁₀₀₁ in the formulae (4A) and (4B).

In the exemplary embodiment, R₁₀₁₁ to R₁₀₁₆ in the formulae (5A) and (5B) are preferably each independently selected from the group consisting of a hydrogen atom and a substituted or unsubstituted alkyl group having 1 to 30 carbon atoms, more preferably a hydrogen atom.

In the formula (4B) of the exemplary embodiment, R₁₀₀₄ and R₁₀₀₁ may be mutually the same or different, B¹ and C¹ may be mutually the same or different, and Ar₁₀₀₁ and Ar₁₀₀₂ may be mutually the same or different. In a case of being mutually the same, it is referred to as a symmetrical unit. In a case of being mutually different, it is referred to as an asymmetric unit. From the viewpoint of easy production by virtue of fewer production processes and fewer by-products, the symmetrical unit is preferred. From the viewpoint of easy adjustment for the emission peak wavelength and the full width at half maximum of emission spectrum based on a combination of the respective groups, the asymmetric unit is preferred.

### Method of Producing First Compound

For instance, the first compound can be produced by a known method as disclosed in International Publication No. WO2020/184369.

### Specific Examples of First Compound

Specific examples of the first compound (compound represented by the formula (1)) according to the exemplary embodiment are shown below. Note that the first compound in the invention is not limited to the specific examples.

A coordinate bond between a boron atom and a nitrogen atom in a pyrromethene skeleton is shown by various means such as a solid line, a broken line, an arrow, and omission. Herein, the coordinate bond is shown by a solid line or a broken line, or the description of the coordinate bond is omitted.

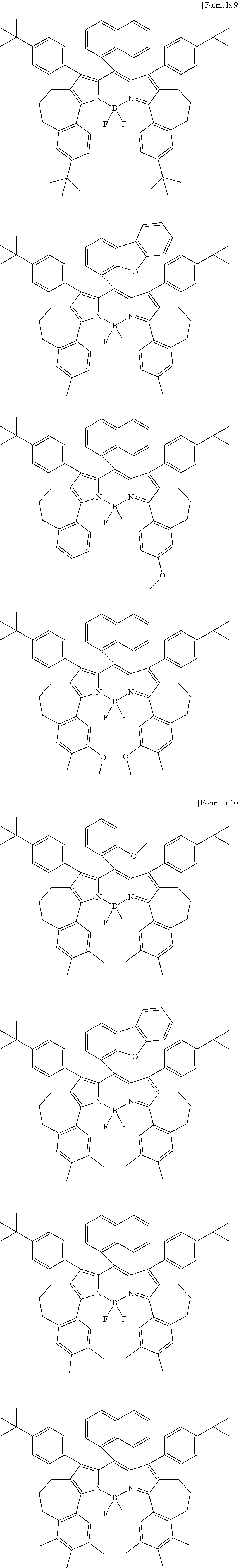

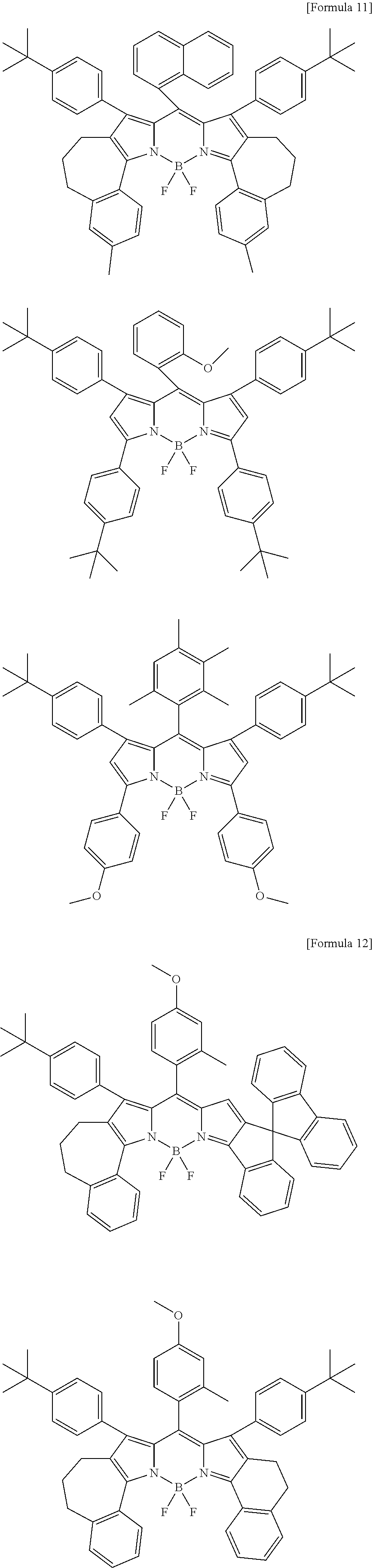

### Second Compound

The second compound is a delayed fluorescent compound.

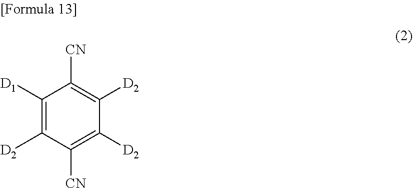

In the formula (2): CN is a cyano group, D₁ is a group represented by a formula (2-1) below, D₂ is a group represented by a formula (2-2) below, and a plurality of D₂ are mutually the same group.

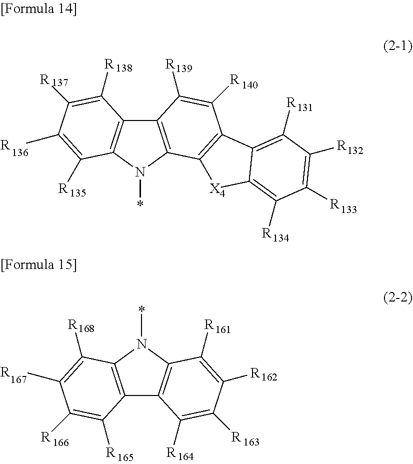

In the formula (2-1):
X₄ is a sulfur atom;
R₁₃₁ to R₁₄₀ are each independently a hydrogen atom or a substituent;
R₁₃₁ to R₁₄₀ as the substituents are each independently a substituted or unsubstituted aryl group having 6 to 14 ring carbon atoms, a substituted or unsubstituted heterocyclic group having 5 to 14 ring atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms; and
* represents a bonding position to a benzene ring in the formula (2).
   In the formula (2-2):
R₁₆₁ to R₁₆₈ are each independently a hydrogen atom or a substituent;
R₁₆₁ to R₁₆₈ as the substituents are each independently a halogen atom, a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted cycloalkyl group having 3 to 30 ring carbon atoms, a substituted or unsubstituted alkyl halide group having 1 to 30 carbon atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms; and
each * independently represents a bonding position to a benzene ring in the formula (2).

In the formulae (2-1) and (2-2), R₁₃₁ to R₁₄₀ and R₁₆₁ to R₁₆₈ are preferably each independently a hydrogen atom, a substituted or unsubstituted aryl group having 6 to 14 ring carbon atoms, or a substituted or unsubstituted heterocyclic group having 5 to 14 ring atoms.

In the formula (2-1), R₁₃₆ is preferably a substituted or unsubstituted aryl group having 6 to 14 ring carbon atoms, or a substituted or unsubstituted heterocyclic group having 5 to 14 ring atoms.

When R₁₃₆ in the formula (2-1) is such an aryl group or heterocyclic group, drive voltage is further reduced in the organic EL device to result in a long lifetime and high luminous efficiency.

### Method of Producing Second Compound

The second compound can be produced by application of known substitution reactions and materials depending on a target compound, in accordance with or based on synthesis methods described later in Examples.

### Specific Examples of Second Compound

Specific examples of the second compound (compound represented by the formula (2)) according to the exemplary embodiment are shown below. Note that the second compound in the invention is not limited to the specific examples.

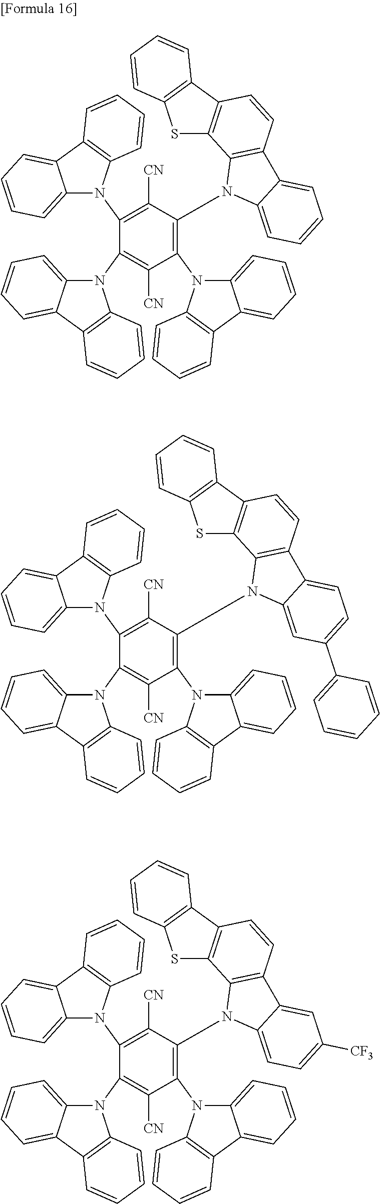 [SMILES: N#Cc1c(-n2c3ccccc3c3ccccc32)c(-n2c3ccccc3c3ccccc32)c(C#N)c(-n2c3ccccc3c3ccc4c5ccccc5sc4c32)c1-n1c2ccccc2c2ccccc21 ; N#Cc1c(-n2c3ccccc3c3ccccc32)c(-n2c3ccccc3c3ccccc32)c(C#N)c(-n2c3cc(-c4ccccc4)ccc3c3ccc4c5ccccc5sc4c32)c1-n1c2ccccc2c2ccccc21 ; N#Cc1c(-n2c3ccccc3c3ccccc32)c(-n2c3ccccc3c3ccccc32)c(C#N)c(-n2c3ccc(C(F)(F)F)cc3c3ccc4c5ccccc5sc4c32)c1-n1c2ccccc2c2ccccc21]

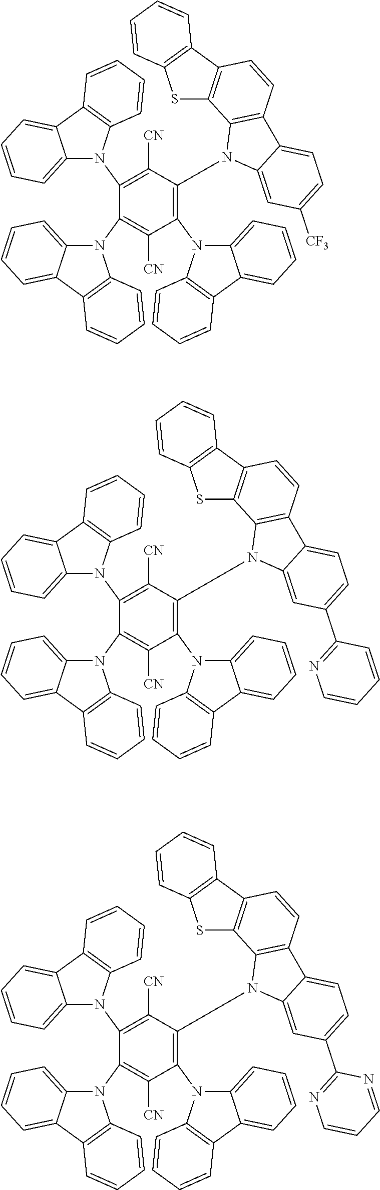 [SMILES: N#Cc1c(-n2c3ccccc3c3ccccc32)c(-n2c3ccccc3c3ccccc32)c(C#N)c(-n2c3cc(C(F)(F)F)ccc3c3ccc4c5ccccc5sc4c32)c1-n1c2ccccc2c2ccccc21 ; N#Cc1c(-n2c3ccccc3c3ccccc32)c(-n2c3ccccc3c3ccccc32)c(C#N)c(-n2c3cc(-c4ccccn4)ccc3c3ccc4c5ccccc5sc4c32)c1-n1c2ccccc2c2ccccc21 ; N#Cc1c(-n2c3ccccc3c3ccccc32)c(-n2c3ccccc3c3ccccc32)c(C#N)c(-n2c3cc(-c4ncccn4)ccc3c3ccc4c5ccccc5sc4c32)c1-n1c2ccccc2c2ccccc21]

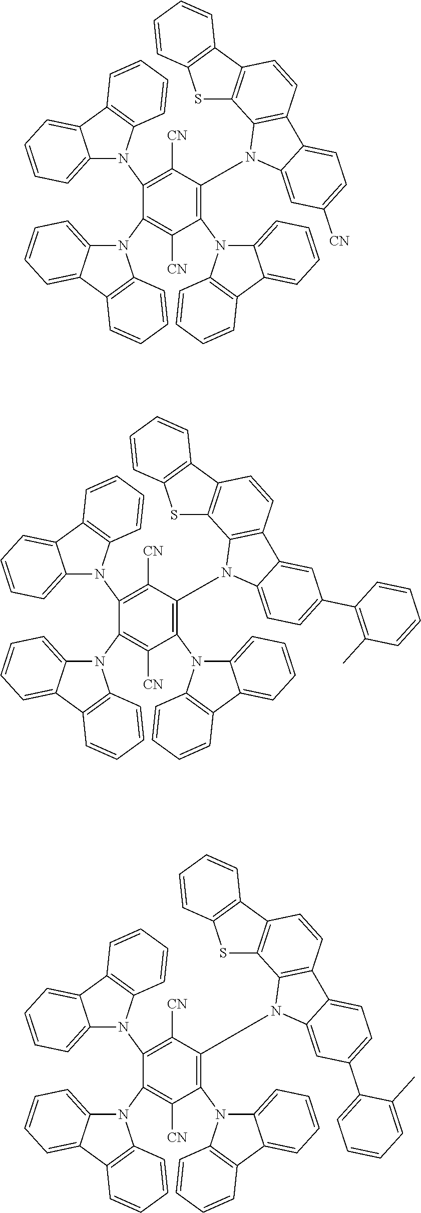 [SMILES: N#Cc1ccc2c3ccc4c5ccccc5sc4c3n(-c3c(C#N)c(-n4c5ccccc5c5ccccc54)c(-n4c5ccccc5c5ccccc54)c(C#N)c3-n3c4ccccc4c4ccccc43)c2c1 ; Cc1ccccc1-c1ccc2c(c1)c1ccc3c4ccccc4sc3c1n2-c1c(C#N)c(-n2c3ccccc3c3ccccc32)c(-n2c3ccccc3c3ccccc32)c(C#N)c1-n1c2ccccc2c2ccccc21 ; Cc1ccccc1-c1ccc2c3ccc4c5ccccc5sc4c3n(-c3c(C#N)c(-n4c5ccccc5c5ccccc54)c(-n4c5ccccc5c5ccccc54)c(C#N)c3-n3c4ccccc4c4ccccc43)c2c1]

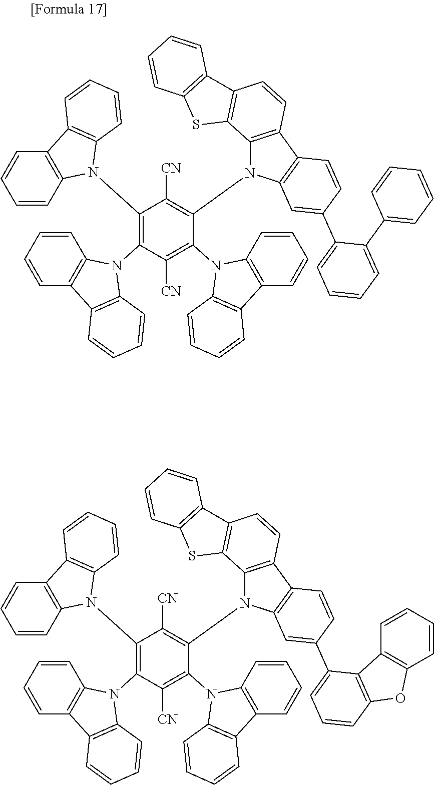 [SMILES: N#Cc1c(-n2c3ccccc3c3ccccc32)c(-n2c3ccccc3c3ccccc32)c(C#N)c(-n2c3cc(-c4ccccc4-c4ccccc4)ccc3c3ccc4c5ccccc5sc4c32)c1-n1c2ccccc2c2ccccc21 ; N#Cc1c(-n2c3ccccc3c3ccccc32)c(-n2c3ccccc3c3ccccc32)c(C#N)c(-n2c3cc(-c4cccc5oc6ccccc6c45)ccc3c3ccc4c5ccccc5sc4c32)c1-n1c2ccccc2c2ccccc21]

### Delayed Fluorescence

Delayed fluorescence is explained in “Yuki Hando-tai no Debaisu Bussei (Device Physics of Organic Semiconductors)” (edited by ADACHI, Chihaya, published by Kodansha, on pages 261-268). This document describes that, if an energy difference ΔE₁₃ of a fluorescent material between a singlet state and a triplet state is reducible, a reverse energy transfer from the triplet state to the singlet state, which usually occurs at a low transition probability, would occur at a high efficiency to express thermally activated delayed fluorescence (TADF). Further, a generation mechanism of delayed fluorescence is explained in FIG. 10.38 in the document. The second compound of the exemplary embodiment is preferably a compound exhibiting thermally activated delayed fluorescence generated by such a mechanism.

In general, emission of delayed fluorescence can be confirmed by measuring the transient PL (Photo Luminescence).

The behavior of delayed fluorescence can also be analyzed based on the decay curve obtained from the transient PL measurement. The transient PL measurement is a method of irradiating a sample with a pulse laser to excite the sample, and measuring the decay behavior (transient characteristics) of PL emission after the irradiation is stopped. PL emission in TADF materials is classified into a light emission component from a singlet exciton generated by the first PL excitation and a light emission component from a singlet exciton generated via a triplet exciton. The lifetime of the singlet exciton generated by the first PL excitation is on the order of nanoseconds and is very short. Therefore, light emission from the singlet exciton rapidly attenuates after irradiation with the pulse laser.

On the other hand, the delayed fluorescence is gradually attenuated due to light emission from a singlet exciton generated via a triplet exciton having a long lifetime. As described above, there is a large temporal difference between the light emission from the singlet exciton generated by the first PL excitation and the light emission from the singlet exciton generated via the triplet exciton. Therefore, the luminous intensity derived from delayed fluorescence can be determined.

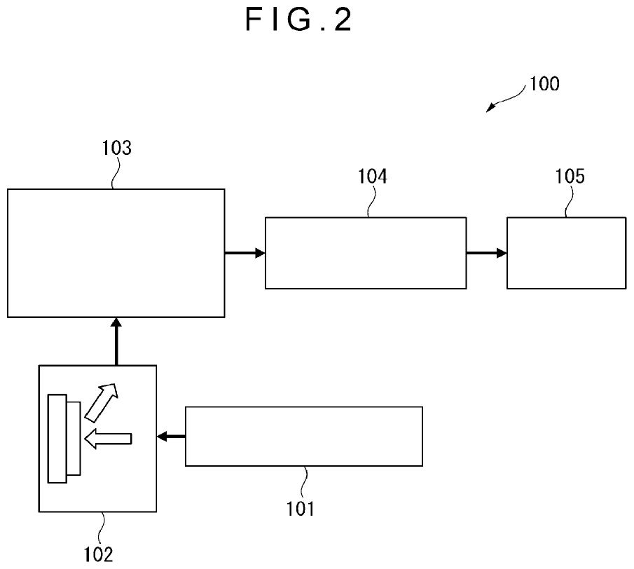

FIG. 2 is a schematic diagram of an exemplary apparatus for measuring the transient PL. An example of a method of measuring a transient PL using FIG. 2 and an example of behavior analysis of delayed fluorescence will be described.

A transient PL measuring apparatus 100 in FIG. 2 includes: a pulse laser 101 capable of radiating light having a predetermined wavelength; a sample chamber 102 configured to house a measurement sample; a spectrometer 103 configured to divide light radiated from the measurement sample; a streak camera 104 configured to provide a two-dimensional image; and a personal computer 105 configured to import and analyze the two-dimensional image. An apparatus for measuring the transient PL is not limited to the apparatus depicted in FIG. 2.

The sample housed in the sample chamber 102 is obtained by forming a thin film, in which a matrix material is doped with a doping material at a concentration of 12 mass %, on the quartz substrate.

The thin film sample housed in the sample chamber 102 is irradiated with the pulse laser from the pulse laser 101 to excite the doping material. Emission is extracted in a direction of 90 degrees with respect to a radiation direction of the excited light. The extracted emission is divided by the spectrometer 103 to form a two-dimensional image in the streak camera 104. As a result, the two-dimensional image is obtainable in which the ordinate axis represents a time, the abscissa axis represents a wavelength, and a bright spot represents a luminous intensity. When this two-dimensional image is taken out at a predetermined time axis, an emission spectrum in which the ordinate axis represents the luminous intensity and the abscissa axis represents the wavelength is obtainable. Moreover, when this two-dimensional image is taken out at the wavelength axis, a decay curve (transient PL) in which the ordinate axis represents a logarithm of the luminous intensity and the abscissa axis represents the time is obtainable.

For instance, a thin film sample A was prepared as described above from a reference compound H1 as the matrix material and a reference compound D1 as the doping material and was measured in terms of the transient PL.

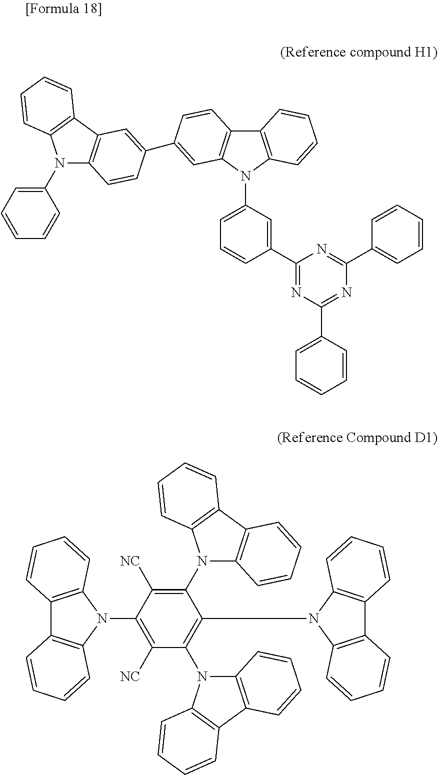 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

The decay curve was analyzed for the above thin film sample A and a thin film sample B. The thin film sample B was produced in the same manner as described above from a reference compound H2 as the matrix material and the reference compound D₁ as the doping material.

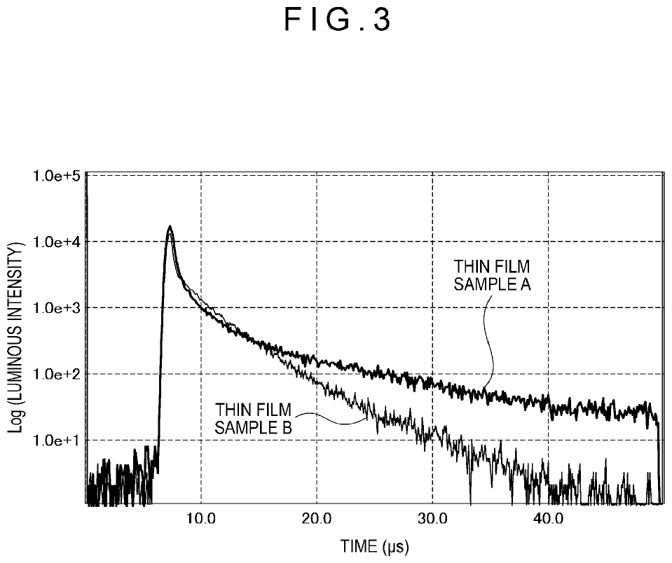

FIG. 3 illustrates decay curves obtained from transient PL obtained by measuring the thin film samples A and B.

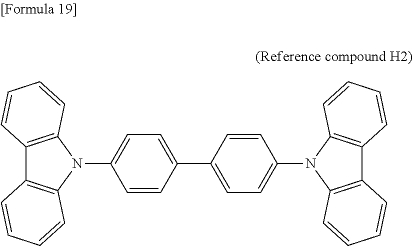 [SMILES: c1ccc2c(c1)c1ccccc1n2-c1ccc(-c2ccc(-n3c4ccccc4c4ccccc43)cc2)cc1]

As described above, an emission decay curve in which the ordinate axis represents the luminous intensity and the abscissa axis represents the time can be obtained by the transient PL measurement. Based on the emission decay curve, a fluorescence intensity ratio between fluorescence emitted from a singlet state generated by photo-excitation and delayed fluorescence emitted from a singlet state generated by reverse energy transfer via a triplet state can be estimated. In a delayed fluorescent material, a ratio of the intensity of the slowly decaying delayed fluorescence to the intensity of the promptly decaying fluorescence is relatively large.

Specifically, Prompt emission and Delay emission are present as emission from the delayed fluorescent material. Prompt emission is observed promptly when the excited state is achieved by exciting the compound of the exemplary embodiment with a pulse beam (i.e., a beam emitted from a pulse laser) having a wavelength absorbable by the delayed fluorescent material. Delay emission is observed not promptly when the excited state is achieved but after the excited state is achieved.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using an apparatus different from one described in Reference Document 1 or one depicted in FIG. 2.

Herein, a sample produced by the following method is used for measuring delayed fluorescence of the second compound. For instance, the second compound is dissolved in toluene to prepare a dilute solution with an absorbance of 0.05 or less at the excitation wavelength to eliminate the contribution of self-absorption. In order to prevent quenching due to oxygen, the sample solution is frozen and degassed and then sealed in a cell with a lid under an argon atmosphere to obtain an oxygen-free sample solution saturated with argon.

The fluorescence spectrum of the sample solution is measured with a spectrofluorometer FP-8600 (produced by JASCO Corporation), and the fluorescence spectrum of a 9,10-diphenylanthracene ethanol solution is measured under the same conditions. Using the fluorescence area intensities of both spectra, the total fluorescence quantum yield is calculated by an equation (1) in Morris et al. J. Phys. Chem. 80 (1976) 969.

In the exemplary embodiment, provided that an amount of Prompt emission of a measurement target compound (second compound) is denoted by XP and an amount of Delay emission is denoted by X_{D}, a value of X_{D}/X_{P} is preferably 0.05 or more.

The amounts of Prompt emission and Delay emission and a ratio of the amounts thereof in any other compounds than the second compound herein are measured in the same manner as those of the second compound.

### Third Compound

The third compound may be a delayed fluorescent compound or a compound that does not exhibit delayed fluorescence.

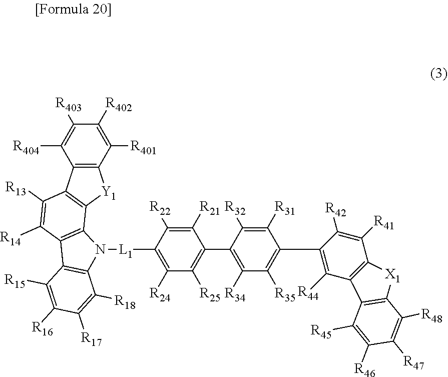

In the formula (3):
X₁ is an oxygen atom or a sulfur atom;
Y₁ is an oxygen atom or a sulfur atom;
L₁ is a single bond or a linking group;
L₁ as the linking group is a group derived from a substituted or unsubstituted aryl group having 6 to 30 ring carbon atoms, a group derived from a substituted or unsubstituted heterocyclic group having 5 to 30 ring atoms, or a group formed by bonding two groups selected from the group consisting of a group derived from a substituted or unsubstituted aryl group having 6 to 30 ring carbon atoms and a group derived from a substituted or unsubstituted heterocyclic group having 5 to 30 ring atoms;
R₄₁, R₄₂ and R₄₄ to R₄₈ are each independently a hydrogen atom or a substituent, or at least one combination of a combination of R₄₁ and R₄₂, a combination of R₄₅ and R₄₆, a combination of R₄₆ and R₄₇, or a combination of R₄₇ and R₄₈ are mutually bonded to form a ring;
R₃₁, R₃₂, R₃₄, and R₃₅ are each independently a hydrogen atom or a substituent;
R₂₁, R₂₂, R₂₄, and R₂₅ are each independently a hydrogen atom or a substituent;
R₁₃ to R₁₈ and R₄₀₁ to R₄₀₄ are each independently a hydrogen atom or a substituent, or at least one combination of a combination of R₁₃ and R₁₄, a combination of R₁₅ and R₁₆, a combination of R₁₆ and R₁₇, a combination of R₁₇ and R₁₈, a combination of R₄₀₁ and R₄₀₂, a combination of R₄₀₂ and R₄₀₃, or a combination of R₄₀₃ and R₄₀₄ are mutually bonded to form a ring; and
R₄₁, R₄₂, R₄₄ to R₄₈, R₃₁, R₃₂, R₃₄, R₃₅, R₂₁, R₂₂, R₂₄, R₂₅, R₁₃ to R₁₈, and R₄₀₁ to R₄₀₄ as the substituents are each independently a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkyl halide group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 60 ring carbon atoms, a substituted or unsubstituted aryl phosphoryl group having 6 to 60 ring carbon atoms, a hydroxy group, a substituted or unsubstituted alkoxy group having 1 to 30 carbon atoms, a substituted or unsubstituted aryloxy group having 6 to 30 ring carbon atoms, amino group, a substituted or unsubstituted alkylamino group having 2 to 30 carbon atoms, a substituted or unsubstituted arylamino group having 6 to 60 ring carbon atoms, a thiol group, a substituted or unsubstituted alkylthio group having 1 to 30 carbon atoms, or a substituted or unsubstituted arylthio group having 6 to 30 ring carbon atoms.

In the formula (3), X₁ is preferably an oxygen atom.

In the formula (3), Y₁ is preferably an oxygen atom.

In the formula (3), L₁ is a single bond or a linking group, and L₁ as the linking group is preferably a group derived from a substituted or unsubstituted aryl group having 6 to 30 ring carbon atoms.

In the formula (3), it is preferable that R₁₃ to R₁₈, R₂₁, R₂₂, R₂₄, R₂₅, R₃₁, R₃₂, R₃₄, R₃₅, R₄₀₁ to R₄₀₄, R₄₁, R₄₂ and R₄₄ to R₄₈ are each independently a hydrogen atom or a substituent, and that R₁₃ to R₁₈, R₂₁, R₂₂, R₂₄, R₂₅, R₃₁, R₃₂, R₃₄, R₃₅, R₄₀₁ to R₄₀₄, R₄₁, R₄₂, and R₄₄ to R₄₈ as the substituents are each independently a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

### Method of Producing Third Compound

The third compound can be produced by a known method.

### Specific Examples of Third Compound

Specific examples of the third compound (compound represented by the formula (3)) according to the exemplary embodiment are shown below. Note that the third compound in the invention is not limited to the specific examples.

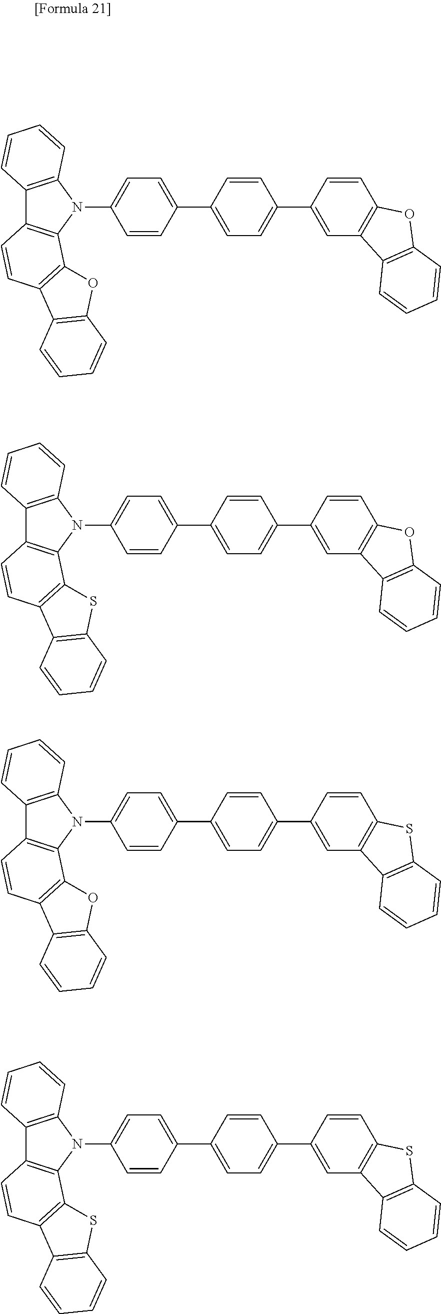 [SMILES: c1ccc2c(c1)oc1ccc(-c3ccc(-c4ccc(-n5c6ccccc6c6ccc7c8ccccc8oc7c65)cc4)cc3)cc12 ; c1ccc2c(c1)oc1ccc(-c3ccc(-c4ccc(-n5c6ccccc6c6ccc7c8ccccc8sc7c65)cc4)cc3)cc12 ; c1ccc2c(c1)oc1c2ccc2c3ccccc3n(-c3ccc(-c4ccc(-c5ccc6sc7ccccc7c6c5)cc4)cc3)c21 ; c1ccc2c(c1)sc1ccc(-c3ccc(-c4ccc(-n5c6ccccc6c6ccc7c8ccccc8sc7c65)cc4)cc3)cc12]

### Relationship Between First Compound, Second Compound and Third Compound in Emitting Layer

In the organic EL device according to the exemplary embodiment, a singlet energy of the first compound S₁(M1), a singlet energy of the second compound S₁(M2), and a single energy of the third compound S₁(M3) in the emitting layer satisfy a relationship of a numerical formula (Numerical Formula 1) below.

S₁(M3)>S₁(M2)>S₁(M1) (Numerical Formula 1)

In the emitting layer, an energy gap at 77K of the first compound T_{77K}(M1), an energy gap at 77K of the second compound T_{77K}(M2), and an energy gap at 77K of the third compound T_{77K}(M3) preferably satisfy a relationship represented by a numerical formula (Numerical Formula 2) below.

T_{77K}(M3)>T_{77K}(M2)>T_{77K}(M1) (Numerical Formula 2)

In the exemplary embodiment, a difference ΔST(M2) between the singlet energy of the second compound S1(M2) and the energy gap at 77K of the second compound T_{77K}(M2) preferably satisfies a relationship represented by one of numerical formulae (Numerical Formula 1A) to (Numerical Formula 1D) below.

ΔST(M2)=S₁(M2)−T_{77K}(M2)<0.3 eV (Numerical Formula 1A)

ΔST(M2)=S₁(M2)−T_{77K}(M2)<0.2 eV (Numerical Formula 1B)

ΔST(M2)=S₁(M2)−T_{77K}(M2)<0.1 eV (Numerical Formula 1C)

ΔST(M2)=S₁(M2)−T_{77K}(M2)<0.01 eV (Numerical Formula 1D)

In the exemplary embodiment, a difference ΔST(M1) between the singlet energy of the first compound S₁(M1) and the energy gap at 77K of the first compound T_{77K}(M1) preferably satisfies a relationship represented by a numerical formula (Numerical Formula 1E) below.

ΔST(M1)=S₁(M1)−T_{77K}(M1)>0.3 [eV] (Numerical Formula 1E)

In the exemplary embodiment, a difference ΔST(M3) between the singlet energy of the third compound S₁(M3) and the energy gap at 77K of the third compound T_{77K}(M3) preferably satisfies a relationship represented by a numerical formula (Numerical Formula 1F) below.

ΔST(M3)=S₁(M3)−T_{77K}(M3)>0.3 [eV] (Numerical Formula 1F)

In the exemplary embodiment, the energy gap at 77K of the third compound T_{77K}(M3) is preferably 2.9 eV or more. It is believed that the third compound having such an energy gap T_{77K}(M3) allows the triplet energy of the second compound (delayed fluorescent compound) to be efficiently trapped in the emitting layer.

### TADF Mechanism

In the organic EL device of the exemplary embodiment, the second compound is preferably a compound having a small ΔST(M2), so that inverse intersystem crossing from the triplet energy level of the second compound to the singlet energy level thereof is easily caused by a heat energy given from the outside. An energy state conversion mechanism to perform spin exchange from the triplet state of electrically excited excitons within the organic EL device to the singlet state by inverse intersystem crossing is referred to as the TADF mechanism.

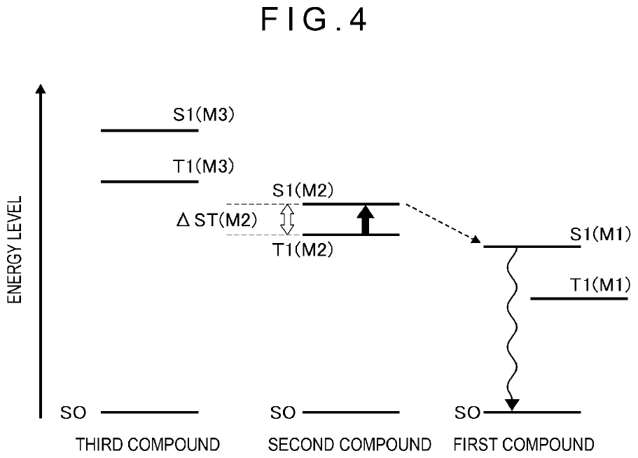

FIG. 4 illustrates an example of a relationship between energy levels of the first compound, the second compound, and the third compound in the emitting layer. In FIG. 4, S0 represents a ground state. S1(M1) represents the lowest singlet state of the first compound. T1(M1) represents the lowest triplet state of the first compound. S1(M2) represents the lowest singlet state of the second compound. T1(M2) represents the lowest triplet state of the second compound. S1(M3) represents the lowest singlet state of the third compound. T1(M3) represents the lowest triplet state of the third compound. A dashed arrow directed from S1(M2) to S1(M1) in FIG. 4 represents Förster energy transfer from the lowest singlet state of the second compound to the lowest singlet state of the first compound.

As illustrated in FIG. 4, when a compound having a small ΔST(M2) is used as the second compound, inverse intersystem crossing from the lowest triplet state T1(M2) to the lowest singlet state S1(M2) can be caused by a heat energy. Subsequently, Förster energy transfer from the lowest singlet state of the second compound S1(M2) to the first compound occurs to generate the lowest singlet state S1(M1). Consequently, fluorescence from the lowest singlet state of the first compound S1(M1) can be observed. It is inferred that the internal quantum efficiency can be theoretically raised up to 100% also by using delayed fluorescence by the TADF mechanism.

### Relationship Between Triplet Energy and Energy Gap at 77K

Here, a relationship between a triplet energy and an energy gap at 77K will be described. In the exemplary embodiment, the energy gap at 77K is different from a typical triplet energy in some aspects.

The triplet energy is measured as follows. First, a solution in which a compound (measurement target) is dissolved in an appropriate solvent is encapsulated in a quartz glass tube to prepare a sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. The triplet energy is calculated by a predetermined conversion equation based on a wavelength value at an intersection of the tangent and the abscissa axis.

Herein, among the compounds of the exemplary embodiment, the thermally activated delayed fluorescent compound is preferably a compound having a small ΔST. When ΔST is small, intersystem crossing and inverse intersystem crossing are likely to occur even at a low temperature (77K), so that the singlet state and the triplet state coexist. As a result, the spectrum to be measured in the same manner as the above includes emission from both the singlet state and the triplet state. Although it is difficult to distinguish from which state, the singlet state or the triplet state, light is emitted, the value of the triplet energy is basically considered dominant.

Accordingly, in the exemplary embodiment, the triplet energy is measured by the same method as a typical triplet energy T, but a value measured in the following manner is referred to as an energy gap T_{77K} in order to differentiate the measured energy from the typical triplet energy in a strict meaning. The measurement target compound is dissolved in EPA (diethylether:isopentane:ethanol=5:5:2 in volume ratio) at a concentration of 10 μmol/L, and the obtained solution is put in a quartz cell to provide a measurement sample. A phosphorescence spectrum (ordinate axis: phosphorescent luminous intensity, abscissa axis: wavelength) of the sample is measured at a low temperature (77K). A tangent is drawn to the rise of the phosphorescence spectrum close to the short-wavelength region. An energy amount is calculated by a conversion equation (F1) below based on a wavelength value λ_{edge} [nm] at an intersection of the tangent and the abscissa axis and is defined as an energy gap T_{77K} at 77K.

T_{77K} [eV]=1239.85/λ_{edge} Conversion Equation (F1):

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (produced by Hitachi High-Technologies Corporation) is usable. Any apparatus for phosphorescence measurement is usable. A combination of a cooling unit, a low temperature container, an excitation light source and a light-receiving unit may be used for phosphorescence measurement.

### Singlet Energy S₁

A method of measuring a singlet energy S₁ with use of a solution (occasionally referred to as a solution method) is exemplified by a method below.

A toluene solution of a measurement target compound at a concentration of 10 μmol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λ_{edge} (nm) at an intersection of the tangent and the abscissa axis is assigned to a conversion equation (F2) below to calculate singlet energy.

S₁ [eV]=1239.8/λ_{edge} Conversion Equation (F2):

Any apparatus for measuring absorption spectrum is usable. For instance, a spectrophotometer (U3310 produced by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

In the exemplary embodiment, a difference (S₁—T_{77K}) between the singlet energy S₁ and the energy gap T_{77K} at 77K is defined as ΔST.

Preferably, mainly the fluorescent compound emits light in the emitting layer when the organic EL device of the exemplary embodiment emits light.

The organic EL device according to the exemplary embodiment preferably emits red light or green light.

When the organic EL device according to the exemplary embodiment emits green light, the maximum peak wavelength of the light emitted from the organic EL device is preferably in a range from 500 nm to 560 nm.

When the organic EL device according to the exemplary embodiment emits red light, the maximum peak wavelength of the light emitted from the organic EL device is preferably in a range from 600 nm to 660 nm.

When the organic EL device according to the exemplary embodiment emits blue light, the maximum peak wavelength of the light emitted from the organic EL device is preferably in a range from 430 nm to 480 nm.

The maximum peak wavelength of the light emitted from the organic EL device is measured as follows.

Voltage is applied to the organic EL device such that a current density becomes 10 mA/cm², where spectral radiance spectrum is measured by a spectroradiometer CS-2000 (produced by Konica Minolta, Inc.). A peak wavelength of an emission spectrum, a luminous intensity of which is the maximum in the obtained spectral radiance spectrum, is measured and defined as the maximum peak wavelength (unit: nm).

### Film Thickness of Emitting Layer

The film thickness of the emitting layer of the organic EL device in the exemplary embodiment is preferably in a range from 5 nm to 50 nm, more preferably in a range from 7 nm to 50 nm, and most preferably in a range from 10 nm to 50 nm. When the film thickness of the emitting layer is 5 nm or more, the formation of the emitting layer and the adjustment of the chromaticity are easy. When the film thickness of the emitting layer is 50 nm or less, an increase in the drive voltage is likely to be reduced.

### Content Ratios of Compounds in Emitting Layer

In the emitting layer of the organic EL device of the exemplary embodiment, the content ratio of the first compound is preferably in a range from 0.01 mass % to 10 mass %, more preferably in a range from 0.01 mass % to 5 mass %, and still more preferably in a range from 0.01 mass % to 1 mass %.

The content ratio of the second compound is preferably in a range from 10 mass % to 80 mass %, more preferably in a range from 10 mass % to 60 mass %, and still more preferably in a range from 20 mass % to 60 mass %.

The content ratio of the third compound is preferably in a range from 10 mass % to 80 mass %.

The upper limit of the total of the content ratios of the first compound, the second compound, and the third compound in the emitting layer is 100 mass %. It should be noted that the emitting layer of the exemplary embodiment may further contain any other material(s) than the first compound, the second compound, and the third compound.

The emitting layer may contain a single type of the first compound or may contain two or more types of the first compound. The emitting layer may contain a single type of the second compound or may contain two or more types of the second compound. The emitting layer may contain a single type of the third compound or may contain two or more types of the third compound.

According to the first exemplary embodiment, the organic EL device with high performance is achievable. According to an exemplary arrangement of the first exemplary embodiment, drive voltage is reduced to provide the organic EL device having a long lifetime. A combination of the first compound represented by the formula (1) and the second compound represented by the formula (2) provides an especially high effect.

The organic EL device according to the first exemplary embodiment is usable in an electronic device such as a display device and a light-emitting unit.

An arrangement of the organic EL device will be further described below. It should be noted that the reference numerals are occasionally omitted below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Moreover, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include Indium Tin Oxide (ITO), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

The elements belonging to the group 1 or 2 of the periodic table, which are a material having a small work function, specifically, an alkali metal such as lithium (Li) and cesium (Cs), an alkaline earth metal such as magnesium (Mg), calcium (Ca) and strontium (Sr), an alloy containing the alkali metal and the alkaline earth metal (e.g., MgAg, AlLi), a rare earth metal such as europium (Eu) and ytterbium (Yb), and an alloy containing the rare earth metal are usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of materials for the cathode include elements belonging to the group 1 or 2 of the periodic table, specifically, an alkali metal such as lithium (Li) and cesium (Cs), an alkaline earth metal such as magnesium (Mg), calcium (Ca) and strontium (Sr), an alloy containing the alkali metal and the alkaline earth metal (e.g., MgAg, AlLi), a rare earth metal such as europium (Eu) and ytterbium (Yb), and an alloy containing the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the highly hole-injectable substance include: an aromatic amine compound, which is a low-molecule organic compound, such as 4,4′,4″-tris(N,N-diphenylamino)triphenylamine (abbreviation: TDATA), 4,4′,4″-tris[N -(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N -phenylamino]benzene (abbreviation: DPA3B), 3-[N-(9-phenylcarbazole-3-yl)-N -phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN).

In addition, a high polymer compound (e.g., oligomer, dendrimer and polymer) is usable as the substance exhibiting a high hole injectability. Examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N,N′-bis(4-butylphenyl)-N,N′-bis(phenyl)benzidine] (abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) is also usable.

### Hole Transporting Layer

The hole transporting layer is a layer containing a highly hole-transporting substance. An aromatic amine compound, carbazole derivative, anthracene derivative and the like are usable for the hole transporting layer. Specific examples of a material for the hole transporting layer include 4,4′-bis[N-(1-naphthyl)-N -phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N -phenylamino]biphenyl (abbreviation: DFLDPBi), 4,4′,4″-tris(N,N -diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

For the hole transporting layer, a carbazole derivative such as CBP, 9-[4-(N -carbazolyl)]phenyl-10-phenylanthracene (CzPA), and 9-phenyl-3-[4-(10-phenyl-9-anthryl)phenyl]-9H-carbazole (PCzPA) and an anthracene derivative such as t-BuDNA, DNA, and DPAnth may be used. A high polymer compound such as poly(N -vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance(s).

When the hole transporting layer includes two or more layers, one of the layers with a larger energy gap is preferably provided closer to the emitting layer.

### Electron Transporting Layer

The electron transporting layer is a layer containing a highly electron-transporting substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is preferably usable. The above-described substances mostly have an electron mobility of 10⁻⁶ cm ²/(V·s) or more. It should be noted that any substance other than the above substance may be used for the electron transporting layer as long as the substance exhibits a higher electron transportability than the hole transportability. The electron transporting layer may be provided in the form of a single layer or a laminate of two or more layers of the above substance(s).

Further, a high polymer compound is usable for the electron transporting layer. For instance, poly[(9,9-dihexylfluorene-2,7-diyl)-co-(pyridine-3,5-diyl)] (abbreviation: PF-Py), poly[(9,9-dioctylfluorene-2,7-diyl)-co-(2,2′-bipyridine-6,6′-diyl)] (abbreviation: PF-BPy) and the like are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method

A method for forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

A thickness of each of the organic layers in the organic EL device according to the exemplary embodiment is not limited except for the above particular description. In general, the thickness preferably ranges from several nanometers to 1 μm because excessively small film thickness is likely to cause defects (e.g. pin holes) and excessively large thickness leads to the necessity of applying high voltage and consequent reduction in efficiency.

### Second Exemplary Embodiment

### Electronic Device

An electronic device according to a second exemplary embodiment is installed with the organic EL device according to the above exemplary embodiment. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

### Modification of Embodiment(s)

The scope of the invention is not limited to the above-described exemplary embodiments but includes any modification and improvement as long as such modification and improvement are compatible with the invention.

For instance, the emitting layer is not limited to a single layer, but may be provided by laminating a plurality of emitting layers. When the organic EL device has the plurality of emitting layers, it is only required that at least one of the emitting layers satisfies the conditions described in the above exemplary embodiments. For instance, the rest of the emitting layers may be a fluorescent emitting layer or a phosphorescent emitting layer with use of emission caused by electron transfer from the triplet excited state directly to the ground state.

When the organic EL device includes a plurality of emitting layers, these emitting layers may be mutually adjacently provided, or may form a so-called tandem organic EL device, in which a plurality of emitting units are layered via an intermediate layer.

For instance, a blocking layer may be provided adjacent to at least one of a side of the emitting layer close to the anode or a side of the emitting layer close to the cathode. The blocking layer is preferably provided in contact with the emitting layer to block at least any of holes, electrons, or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer is preferably interposed between the emitting layer and the electron transporting layer.

When the blocking layer is provided in contact with the side of the emitting layer close to the anode, the blocking layer permits transport of holes and blocks electrons from reaching a layer provided closer to the anode (e.g., the hole transporting layer) beyond the blocking layer. When the organic EL device includes the hole transporting layer, the blocking layer is preferably interposed between the emitting layer and the hole transporting layer.

Alternatively, the blocking layer may be provided adjacent to the emitting layer so that the excitation energy does not leak out from the emitting layer toward neighboring layer(s). The blocking layer blocks excitons generated in the emitting layer from being transferred to a layer(s) (e.g., the electron transporting layer and the hole transporting layer) closer to the electrode(s) beyond the blocking layer.

The emitting layer is preferably bonded with the blocking layer.

Specific structure, shape and the like of the components in the invention may be designed in any manner as long as an object of the invention can be achieved.

Herein, numerical ranges represented by “x to y” represents a range whose lower limit is the value (x) recited before “to” and whose upper limit is the value (y) recited after “to.”

Rx and Ry are mutually bonded to form a ring, which means herein, for instance, that Rx and Ry contain a carbon atom, a nitrogen atom, an oxygen atom, a sulfur atom, a phosphorus atom or a silicon atom, the atom (a carbon atom, a nitrogen atom, an oxygen atom, a sulfur atom, a phosphorus atom or a silicon atom) contained in Rx and the atom (a carbon atom, a nitrogen atom, an oxygen atom, a sulfur atom, a phosphorus atom or a silicon atom) contained in Ry are mutually bonded through a single bond, a double bond, a triple bond or a divalent linking group to form a ring having 5 or more ring atoms (specifically, a heterocyclic ring or an aromatic hydrocarbon ring). x represents a number, a character or a combination of a number and a character. y represents a number, a character or a combination of a number and a character.

The divalent linking group is not particularly limited. Examples of the divalent linking group include —O—, —CO—, —CO₂—, —S—, —SO—, —SO₂—, —NH—, —NRa—, and a group provided by a combination of two or more of these linking group.

Specific examples of the heterocyclic ring herein include, unless otherwise described, a cyclic structure (heterocyclic ring) obtained by removing a bond from a “heteroaryl group Sub₂” exemplarily shown in the later-described “Description of Each Substituent in Formulae.” The heterocyclic ring may have a substituent.

Specific examples of the aromatic hydrocarbon ring herein include, unless otherwise described, a cyclic structure (aromatic hydrocarbon ring) obtained by removing a bond from an “aryl group Sub₁” exemplarily shown in the later-described “Description of Each Substituent in Formulae.” The aromatic hydrocarbon ring may have a substituent.

Examples of Ra include a substituted or unsubstituted alkyl group Subs having 1 to 30 carbon atoms, a substituted or unsubstituted aryl group Sub₁ having 6 to 30 ring carbon atoms, and a substituted or unsubstituted heteroaryl group Sub₂ having 5 to 30 ring atoms, which are exemplarily shown in the later-described “Description of Each Substituent in Formulae.”

Rx and Ry are mutually bonded to form a ring, which means, for instance, that: an atom included in Rx₁ and an atom included in Ry₁ in a molecular structure represented by a formula (E1) below form a ring (cyclic structure) E represented by a formula (E2); an atom included in Rx₁ and an atom included in Ry₁ in a molecular structure represented by a formula (F1) below form a ring F represented by a formula (F2); an atom included in Rx₁ and an atom included in Ry₁ in a molecular structure represented by a formula (G1) below form a ring G represented by a formula (G2); an atom included in Rx₁ and an atom included in Ry₁ in a molecular structure represented by a formula (H1) below form a ring H represented by a formula (H2); and an atom included in Rx₁ and an atom included in Ry₁ in a molecular structure represented by a formula (I1) below form a ring I represented by a formula (I2).

In the formulae (E1) to (I1), each * independently represents a bonding position to another atom in a molecule. The two * in the formulae (E1), (F1), (G1), (H1) and (I1) correspond to two * in the formulae (E2), (F2), (G2), (H2) and (I2), respectively.

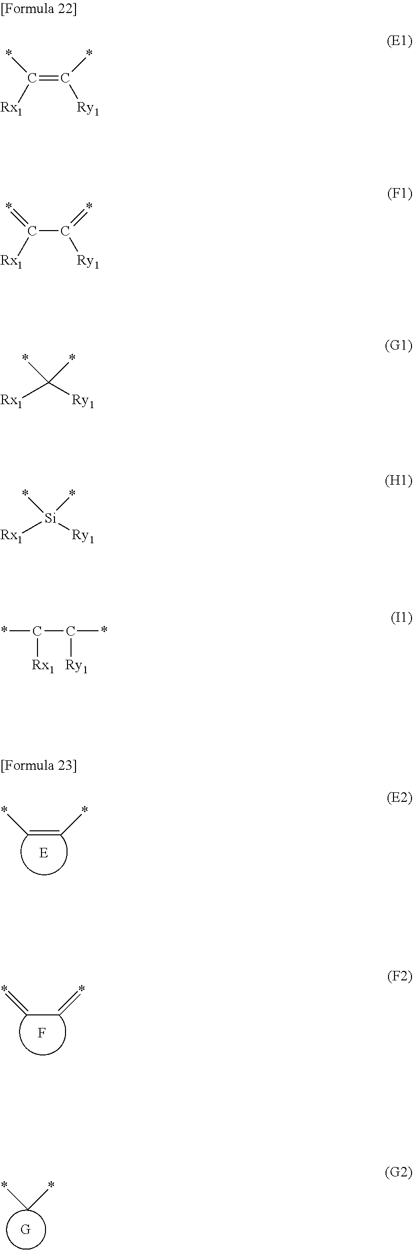

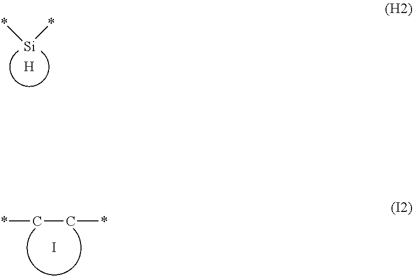

In the molecular structures represented by the formulae (E2) to (I2), E to I each represent a cyclic structure (the ring having 5 or more ring atoms). In the formulae (E2) to (I2), each * independently represents a bonding position to another atom in a molecule. The two * in the formula (E2) correspond to two * in the formula (E1). Similarly, two * in each of the formulae (F2) to (I2) correspond one-to-one to two * in each of the formulae (F1) to (I1).

For instance, in the formula (E1), when Rx₁ and Ry₁ are mutually bonded to form a ring E in the formula (E2) and the ring E is an unsubstituted benzene ring, the molecular structure represented by the formula (E1) is a molecular structure represented by a formula (E3) below. Here, the two * in the formula (E3) each independently correspond to two * in each of the formulae (E1) and (E2).

For instance, in the formula (E1), when Rx₁ and Ry₁ are mutually bonded to form a ring E in the formula (E2) and the ring E is an unsubstituted pyrrole ring, the molecular structure represented by the formula (E1) is a molecular structure represented by a formula (E4) below. Here, the two * in the formula (E4) each independently correspond to two * in each of the formulae (E1) and (E2). In the formulae (E3) to (E4), each * independently represents a bonding position to another atom in a molecule.

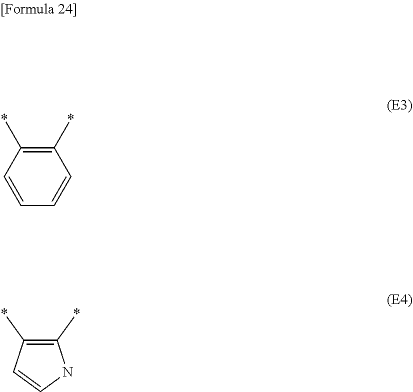 [SMILES: *c1ccccc1* ; *c1cc[nH]c1*]

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) included in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridinyl group has 5 ring carbon atoms, and a furanyl group has 4 ring carbon atoms. When a benzene ring and/or a naphthalene ring is substituted by a substituent (e.g., an alkyl group), the number of carbon atoms of the alkyl group is not counted in the number of the ring carbon atoms. When a fluorene ring is substituted by a substituent (e.g., a fluorene ring) (i.e., a spirofluorene ring is included), the number of carbon atoms of the fluorene ring as a substituent is not counted in the number of the ring carbon atoms of the fluorene ring.

Herein, the ring atoms refer to the number of atoms forming a ring of a compound (e.g., a monocyclic compound, fused-ring compound, crosslinking compound, carbon ring compound, and heterocyclic compound) in which the atoms are bonded to each other to form the ring (e.g., monocyclic ring, fused ring, ring assembly). Atom(s) not forming a ring and atom(s) included in a substituent when the ring is substituted by the substituent are not counted in the number of the ring atoms. Unless specifically described, the same applies to the “ring atoms” described later. For instance, a pyridine ring has six ring atoms, a quinazoline ring has ten ring atoms, and a furan ring has five ring atoms. A hydrogen atom(s) and/or an atom(s) of a substituent which are bonded to carbon atoms of a pyridine ring and/or quinazoline ring are not counted in the ring atoms. When a fluorene ring is substituted by a substituent (e.g., a fluorene ring) (i.e., a spirofluorene ring is included), the number of atoms of the fluorene ring as a substituent is not counted in the number of the ring atoms of the fluorene ring.

### Description of Each Substituent in Formulae

Explanation is made about each substituent in formulae herein.

### Aryl Group

The aryl group (occasionally referred to as an aromatic hydrocarbon group) herein is exemplified by an aryl group Sub₁. The aryl group Sub₁ is, for instance, at least one group selected from the group consisting of a phenyl group, biphenyl group, terphenyl group, naphthyl group, anthryl group, phenanthryl group, fluorenyl group, pyrenyl group, chrysenyl group, fluoranthenyl group, benz[a]anthryl group, benzo[c]phenanthryl group, triphenylenyl group, benzo[k]fluoranthenyl group, benzo[g]chrysenyl group, benzo[b]triphenylenyl group, picenyl group, and perylenyl group.

The aryl group Sub₁ herein preferably has 6 to 30 ring carbon atoms, more preferably 6 to 20 ring carbon atoms, still more preferably 6 to 14 ring carbon atoms, and still further more preferably 6 to 12 ring carbon atoms. Among the aryl group Sub₁, a phenyl group, biphenyl group, naphthyl group, phenanthryl group, terphenyl group and fluorenyl group are preferable. A carbon atom in a position 9 of each of 1-fluorenyl group, 2-fluorenyl group, 3-fluorenyl group and 4-fluorenyl group is preferably substituted by a substituted or unsubstituted alkyl group Sub₃ described later herein or a substituted or unsubstituted aryl group Sub₁.

### Heterocyclic Group

The heteroaryl group (occasionally referred to as a heterocyclic group, heteroaromatic cyclic group or aromatic heterocyclic group) herein is exemplified by a heterocyclic group Sub₂. The heterocyclic group Sub₂ is a group containing, as a hetero atom(s), at least one atom selected from the group consisting of nitrogen, sulfur, oxygen, silicon, selenium atom and germanium atom. The heterocyclic group Sub₂ preferably contains, as a hetero atom(s), at least one atom selected from the group consisting of nitrogen, sulfur and oxygen.

The heterocyclic group Sub₂ herein is, for instance, at least one group selected from the group consisting of a pyridyl group, pyrimidinyl group, pyrazinyl group, pyridazinyl group, triazinyl group, quinolyl group, isoquinolinyl group, naphthyridinyl group, phthalazinyl group, quinoxalinyl group, quinazolinyl group, phenanthridinyl group, acridinyl group, phenanthrolinyl group, pyrrolyl group, imidazolyl group, pyrazolyl group, triazolyl group, tetrazolyl group, indolyl group, benzimidazolyl group, indazolyl group, imidazopyridinyl group, benzotriazolyl group, carbazolyl group, furyl group, thienyl group, oxazolyl group, thiazolyl group, isoxazolyl group, isothiazolyl group, oxadiazolyl group, thiadiazolyl group, benzofuranyl group, benzothienyl group, benzoxazolyl group, benzothiazolyl group, benzisoxazolyl group, benzisothiazolyl group, benzoxadiazolyl group, benzothiadiazolyl group, dibenzofuranyl group, dibenzothienyl group, piperidinyl group, pyrrolidinyl group, piperazinyl group, morpholyl group, phenazinyl group, phenothiazinyl group, and phenoxazinyl group.

The heterocyclic group Sub₂ herein preferably has 5 to 30 ring atoms, more preferably 5 to 20 ring atoms, and still more preferably 5 to 14 ring atoms. Among the above heterocyclic group Sub₂, a 1-dibenzofuranyl group, 2-dibenzofuranyl group, 3-dibenzofuranyl group, 4-dibenzofuranyl group, 1-dibenzothienyl group, 2-dibenzothienyl group, 3-dibenzothienyl group, 4-dibenzothienyl group, 1-carbazolyl group, 2-carbazolyl group, 3-carbazolyl group, 4-carbazolyl group, and 9-carbazolyl group are still more preferable. A nitrogen atom in a position 9 of each of 1-carbazolyl group, 2-carbazolyl group, 3-carbazolyl group and 4-carbazolyl group is preferably substituted by a substituted or unsubstituted aryl group Sub₁ or a substituted or unsubstituted heterocyclic group Sub₂ described herein.

Herein, the heterocyclic group Sub₂ may be a group derived from any one of partial structures represented by formulae (XY-1) to (XY-18) below.

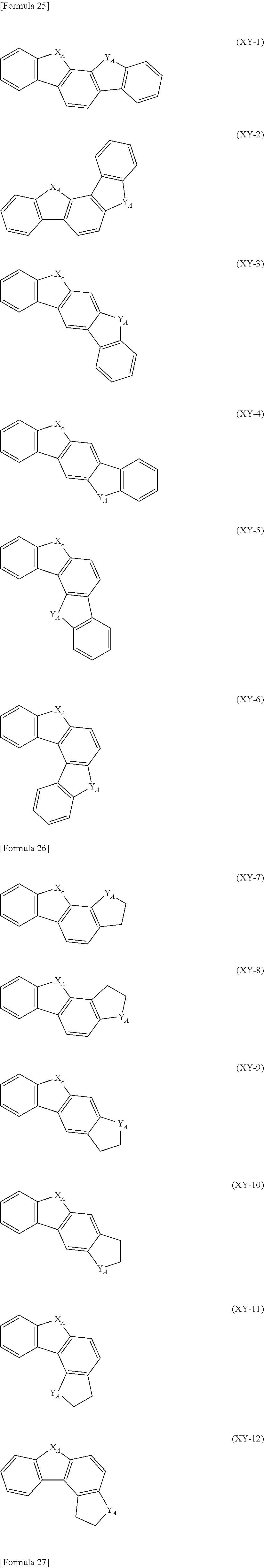

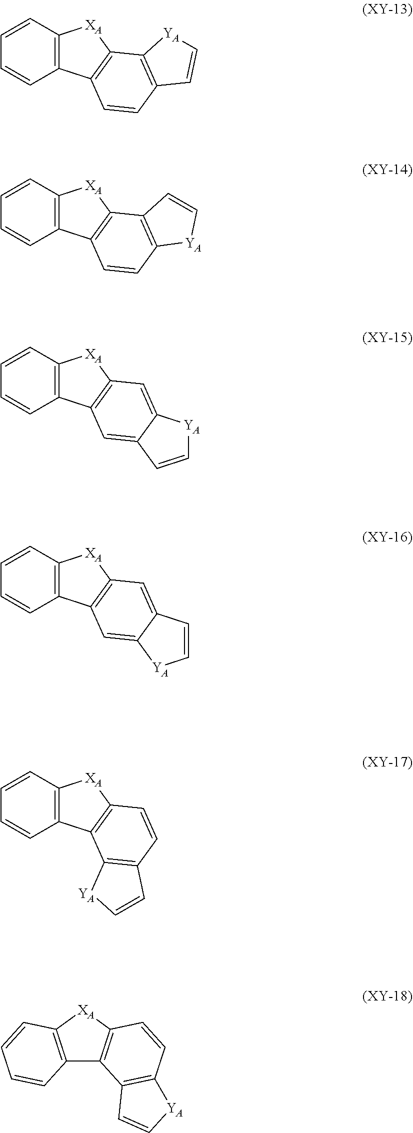

In the formulae (XY-1) to (XY-18), X_{A} and Y_{A} each independently represent a hetero atom, and preferably represent an oxygen atom, sulfur atom, selenium atom, silicon atom or germanium atom. The partial structures represented by the formulae (XY-1) to (XY-18) may each have a bond at any position to provide a heterocyclic group, in which the heterocyclic group may be substituted.

Herein, the heterocyclic group Sub2 may be a group represented by one of formulae (XY-19) to (XY-22) below. Further, the position of the bond may be changed as needed.

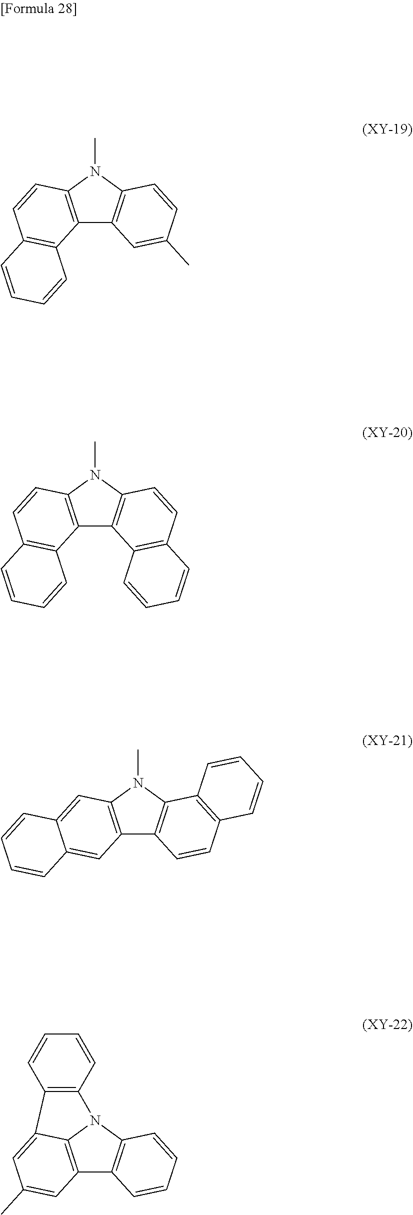

### Alkyl Group

The alkyl group herein may be either a linear alkyl group or branched alkyl group.

The alkyl group herein is exemplified by an alkyl group Sub₃.

The linear alkyl group herein is exemplified by a linear alkyl group Sub₃₁.

The branched alkyl group herein is exemplified by a branched alkyl group Sub₃₂.

For instance, the alkyl group Sub₃ is at least one group selected from the group consisting of the linear alkyl group Sub₃₁ and the branched alkyl group Sub₃₂.

The linear alkyl group Sub₃₁ or branched alkyl group Sub₃₂ is exemplified by at least one group selected from the group consisting of a methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, amyl group, isoamyl group, 1-methylpentyl group, 2-methylpentyl group, 1-pentylhexyl group, 1-butylpentyl group, 1-heptyloctyl group, and 3-methylpentyl group.

### Linear Alkyl Group or Branched Alkyl Group

Herein, the linear alkyl group Sub₃₁ or branched alkyl group Sub₃₂ preferably has 1 to 30 carbon atoms, more preferably 1 to 20 carbon atoms, still more preferably 1 to 10 carbon atoms, and still further more preferably 1 to 6 carbon atoms. The linear alkyl group Sub₃₁ or branched alkyl group Sub₃₂ is still more preferably a methyl group, ethyl group, propyl group, isopropyl group, n-butyl group, s-butyl group, isobutyl group, t-butyl group, n-pentyl group, n-hexyl group, amyl group, isoamyl group and neopentyl group.

### Cyclic Alkyl Group

The cyclic alkyl group herein is exemplified by a cyclic alkyl group Sub₃₃. The cyclic alkyl group Sub₃₃ herein is exemplified by a cycloalkyl group Sub₃₃₁.

The cycloalkyl group Sub₃₃₁ herein is exemplified by at least one group selected from the group consisting of a cyclopropyl group, cyclobutyl group, cyclopentyl group, cyclohexyl group, 4-metylcyclohexyl group, adamantyl group and norbornyl group. The cycloalkyl group Sub₃₃₁ preferably has 3 to 30 ring carbon atoms, more preferably 3 to 20 ring carbon atoms, still more preferably 3 to 10 ring carbon atoms, and still further more preferably 5 to 8 ring carbon atoms. Among the cycloalkyl group Sub₃₃₁, a cyclopentyl group and a cyclohexyl group are still more preferable.

### Alkyl Halide Group

Herein, an alkyl halide group is exemplified by an alkyl halide group Sub₄. The alkyl halide group Sub₄ is provided by substituting the alkyl group Sub₃ with at least one halogen atom, preferably at least one fluorine atom.

Herein, the alkyl halide group Sub₄ is exemplified by at least one group selected from the group consisting of a fluoromethyl group, difluoromethyl group, trifluoromethyl group, fluoroethyl group, trifluoromethylmethyl group, trifluoroethyl group, and pentafluoroethyl group. The alkyl halide group Sub₄ preferably has 1 to 30 carbon atoms, more preferably 1 to 10 carbon atoms, and still more preferably 1 to 6 carbon atoms.

### Substituted Silyl Group

Herein, a substituted silyl group is exemplified by a substituted silyl group Sub₅. The substituted silyl group Sub₅ is exemplified by at least one group selected from the group consisting of an alkylsilyl group Sub₅₁ and an arylsilyl group Sub₅₂.

Herein, the alkylsilyl group Sub₅₁ is exemplified by a trialkylsilyl group Sub₅₁₁ having the above-described alkyl group Sub₃. The alkylsilyl group Sub₅₁ preferably has 3 to 30 carbon atoms, more preferably 3 to 10 carbon atoms, and still more preferably 3 to 6 carbon atoms.

The trialkylsilyl group Sub₅₁₁ is exemplified by at least one group selected from the group consisting of a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyl dimethylsilyl group, propyldimethylsilyl group, and triisopropylsilyl group. Three alkyl groups Sub₃ in the trialkylsilyl group Sub₅₁₁ may be mutually the same or different.

Herein, the arylsilyl group Sub₅₂ is exemplified by at least one group selected from the group consisting of a dialkylarylsilyl group Sub₅₂₁, alkyldiarylsilyl group Sub₅₂₂ and triarylsilyl group Sub₅₂₃. The arylsilyl group Sub₅₂ preferably has 6 to 60 ring carbon atoms.

The dialkylarylsilyl group Sub₅₂₁ is exemplified by a dialkylarylsilyl group including two alkyl groups Sub₃ and one aryl group Sub₁. The dialkylarylsilyl group Sub₅₂₁preferably has 8 to 30 carbon atoms.

The alkyldiarylsilyl group Sub₅₂₂ is exemplified by an alkyldiarylsilyl group including one alkyl group Sub₃ and two aryl groups Sub₁. The alkyldiarylsilyl group Sub₅₂₂ preferably has 13 to 30 carbon atoms.

The triarylsilyl group Sub₅₂₃ is exemplified by a triarylsilyl group including three aryl groups Sub₁. The triarylsilyl group Sub₅₂₃ preferably has 18 to 30 carbon atoms.

### Alkyl Sulfonyl Group

Herein, a substituted or unsubstituted alkyl sulfonyl group is exemplified by an alkyl sulfonyl group Sub₆. The alkyl sulfonyl group Sub₆ is represented by —SO₂R_{w}. R_{W} in —SO₂R_{w} represents a substituted or unsubstituted alkyl group Sub₃ described above.

### Aralkyl Group

Herein, an aralkyl group (occasionally referred to as an arylalkyl group) is exemplified by an aralkyl group Sub₇. An aryl group in the aralkyl group Sub₇ includes, for instance, at least one of the above-described aryl group Sub₁ or the above-described heteroaryl group Sub₂.

The aralkyl group Sub₇ herein is preferably a group having the aryl group Sub₁ and is represented by —Z₃—Z₄. Z₃ is exemplified by an alkylene group corresponding to the above alkyl group Sub₃. Z₄ is exemplified by the above aryl group Sub₁. In this aralkyl group Sub₇, an aryl moiety has 6 to 30 carbon atoms (preferably 6 to 20 carbon atoms, more preferably 6 to 12 carbon atoms) and an alkyl moiety has 1 to 30 carbon atoms (preferably 1 to 20 carbon atoms, more preferably 1 to 10 carbon atoms, and still more preferably 1 to 6 carbon atoms). The aralkyl group Sub₇ is exemplified by at least one group selected from the group consisting of a benzyl group, 2-phenylpropane-2-yl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

### Alkoxy Group

The alkoxy group herein is exemplified by an alkoxy group Sub₈. The alkoxy group Sub₈ is represented by −OZ₁. Z₁ is exemplified by the above alkyl group Sub₃. The alkoxy group Sub₈ is exemplified by at least one group selected from the group consisting of a methoxy group, ethoxy group, propoxy group, butoxy group, pentyloxy group and hexyloxy group. The alkoxy group Sub₈ preferably has 1 to 30 carbon atoms, more preferably 1 to 20 carbon atoms, and still more preferably 1 to 6 carbon atoms.

### Alkoxy Halide Group

Herein, an alkoxy halide group is exemplified by an alkoxy halide group Sub₉. The alkoxy halide group Sub₉ is provided, for instance, by substituting the alkoxy group Sub₈ with at least one halogen atom, preferably at least one fluorine atom. The alkoxy halide group Sub₉ preferably has 1 to 30 carbon atoms, more preferably 1 to 10 carbon atoms, and still more preferably 1 to 6 carbon atoms.

### Aryloxy Group

Herein, an aryloxy group (occasionally referred to as an arylalkoxy group) is exemplified by an arylalkoxy group Sub₁₀. An aryl group in the arylalkoxy group Sub₁₀ includes at least one of the aryl group Sub₁ or the heteroaryl group Sub₂.

The arylalkoxy group Sub₁₀ herein is represented by —OZ₂. Z₂ is exemplified by the aryl group Sub₁ or the heteroaryl group Sub₂. The arylalkoxy group Sub₁₀ preferably has 6 to 30 ring carbon atoms, more preferably 6 to 20 ring carbon atoms, and still more preferably 6 to 14 ring carbon atoms. The arylalkoxy group Sub₁₀ is exemplified by a phenoxy group.

### Substituted Amino Group

Herein, a substituted amino group is exemplified by a substituted amino group Sub₁₁. The substituted amino group Sub₁₁ is exemplified by at least one group selected from the group consisting of an arylamino group Sub₁₁₁ and an alkylamino group Sub₁₁₂.

The arylamino group Sub₁₁₁ is represented by —NHR_{V1} or —N(R_{V1})₂. R_{V1} is exemplified by the aryl group Sub₁. Two R_{V1} in —N(R_{V1})₂ are mutually the same or different. The arylamino group Sub₁₁₁ preferably has 6 to 60 ring carbon atoms.

The alkylamino group Sub₁₁₂ is represented by —NHR_{V2} or —N(R_{V2})₂. R_{V2} is exemplified by the alkyl group Sub₃. Two R_{V2} in —N(R_{V2})₂ are mutually the same or different. The alkylamino group Sub₁₁₂ preferably has 2 to 30 carbon atoms, more preferably 2 to 12 carbon atoms.

### Alkenyl Group

Herein, the alkenyl group is exemplified by an alkenyl group Sub₁₂. The alkenyl group Sub₁₂, which is linear or branched, is exemplified by at least one group selected from the group consisting of a vinyl group, propenyl group, butenyl group, oleyl group, eicosapentaenyl group, docosahexaenyl group, styryl group, 2,2-diphenylvinyl group, 1,2,2-triphenylvinyl group, and 2-phenyl-2-propenyl group. The alkenyl group Sub₁₂ preferably has 2 to 30 carbon atoms.

### Cycloalkenyl Group

Herein, a cycloalkenyl group is an unsaturated aliphatic hydrocarbon group including a double bond. The cycloalkenyl group is exemplified by a cycloalkenyl group Sub₁₂₂. The cycloalkenyl group Sub₁₂₂ is exemplified by at least one group selected from the group consisting of a cyclopentenyl group, cyclopentadienyl group, and cyclohexenyl group. The cycloalkenyl group Sub₁₂₂ preferably has 3 to 30 ring carbon atoms.

### Alkynyl Group

The alkynyl group herein is exemplified by an alkynyl group Sub₁₃. The alkynyl group Sub₁₃ may be linear or branched and is at least one group selected from the group consisting of an ethynyl group, a propynyl group and a 2-phenylethynyl group. The alkynyl group Sub₁₃ preferably has 2 to 30 carbon atoms.

### Alkylthio Group

The alkylthio group herein is exemplified by an alkylthio group Sub₁₄.

The alkylthio group Sub₁₄ is represented by —SR_{V3}. R_{V3} is exemplified by the alkyl group Sub₃. The alkylthio group Sub₁₄ preferably has 1 to 30 carbon atoms, more preferably 1 to 20 carbon atoms, and still more preferably 1 to 6 carbon atoms.

### Arylthio Group

The arylthio group herein is exemplified by an arylthio group Sub₁₅.

The arylthio group Sub₁₅ is represented by —SR_{V4}. R_{V4} is exemplified by the aryl group Sub₁. The arylthio group Sub₁₅ preferably has 6 to 30 ring carbon atoms, more preferably 6 to 20 ring carbon atoms, and still more preferably 6 to 14 ring carbon atoms.

### Halogen Atom

Herein, examples of the halogen atom include a fluorine atom, a chlorine atom, a bromine atom and an iodine atom, among which a fluorine atom is preferable.

### Substituted Phosphino Group

A substituted phosphino group herein is exemplified by a substituted phosphino group Sub₁₆. The substituted phosphino group Sub₁₆ is exemplified by a phenyl phosphanyl group.

### Arylcarbonyl Group

An arylcarbonyl group herein is exemplified by an arylcarbonyl group Sub₁₇. The arylcarbonyl group Sub₁₇ is represented by —COY′. Y′ is exemplified by the aryl group Sub₁. Herein, the arylcarbonyl group Sub₁₇ is exemplified by at least one group selected from the group consisting of a phenyl carbonyl group, diphenyl carbonyl group, naphthyl carbonyl group, and triphenyl carbonyl group.

### Acyl Group

An acyl group herein is exemplified by an acyl group Sub₁₈. The acyl group Sub₁₈ is represented by −COR′. R′ is exemplified by at least one group selected from the group consisting of the alkyl group Sub₃, cycloalkyl group Sub₃₃₁, alkenyl group Sub₁₂, alkynyl group Sub₁₃, aryl group Sub₁, and heterocyclic group Sub₂, and the alkyl group Sub₃, cycloalkyl group Sub₃₃₁, alkenyl group Sub₁₂, alkynyl group Sub₁₃, aryl group Sub₁, and heterocyclic group Sub₂ may be further substituted. The acyl group Sub₁₈ herein is exemplified by at least one group selected from the group consisting of an acetyl group, propionyl group, benzoyl group, and acryloyl group. Although not particularly limited, the acyl group Sub₁₈ preferably has 2 to 40 carbon atoms, more preferably 2 to 30 carbon atoms.

### Substituted Phosphoryl Group

A substituted phosphoryl group herein is exemplified by a substituted phosphoryl group Sub₁₉ such as an aryl phosphoryl group and alkyl phosphoryl group. The substituted phosphoryl group Sub₁₉ is represented by a formula (P) below.

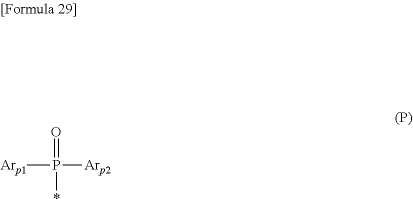

In the formula (P), Ar_{P1} and Ar_{P2} are any one substituent selected from the group consisting of the above alkyl group Sub₃ and the above aryl group Sub₁. The aryl phosphoryl group preferably has 6 to 60 ring carbon atoms.

### Ester Group

An ester group herein is exemplified by an ester group Sub₂₀. The ester group Sub₂₀ is exemplified by at least one group selected from the group consisting of an alkyl ester group and an aryl ester group.

An alkyl ester group herein is exemplified by an alkyl ester group Sub₂₀₁. The alkyl ester group Sub₂₀₁ is represented by —C(═O)OR^{E}. R^{E} is exemplified by a substituted or unsubstituted alkyl group Sub₃ described above.

An aryl ester group herein is exemplified by an aryl ester group Sub₂₀₂. The aryl ester group Sub₂₀₂ is represented by —C(═O)OR^{Ar}. R^{Ar} is exemplified by a substituted or unsubstituted aryl group Sub₁ described above.

### Siloxanyl Group

A siloxanyl group herein is exemplified by a siloxanyl group Sub₂₁. The siloxanyl group Sub₂₁ is a silicon compound group through an ether bond. The siloxanyl group Sub₂₁ is exemplified by a trimethylsiloxanyl group.

### Carbamoyl Group

A carbamoyl group herein is represented by —CONH₂.

A substituted carbamoyl group herein is exemplified by a carbamoyl group Sub₂₂. The carbamoyl group Sub₂₂ is represented by —CONH—Ar^{C} or —CONH—R^{C}. Ar^{C} is exemplified by at least one group selected from the group consisting of a substituted or unsubstituted aryl group Sub₁ described above (preferably 6 to 10 ring carbon atoms) and the above-described heteroaryl group Sub₂ (preferably 5 to 14 ring atoms). Ar^{C} may be a group formed by bonding the aryl group Sub₁ and the heteroaryl group Sub₂.

R^{C} is exemplified by a substituted or unsubstituted alkyl group Sub₃ described above (preferably having 1 to 6 carbon atoms).

Herein, “carbon atoms forming a ring (ring carbon atoms)” mean carbon atoms forming a saturated ring, unsaturated ring, or aromatic ring. “Atoms forming a ring (ring atoms)” mean carbon atoms and hetero atoms forming a hetero ring including a saturated ring, unsaturated ring, or aromatic ring.

Herein, a hydrogen atom includes isotope having different numbers of neutrons, specifically, protium, deuterium and tritium.

Hereinafter, an alkyl group Sub₃ means at least one group of a linear alkyl group Sub₃₁, a branched alkyl group Sub₃₂, or a cyclic alkyl group Sub₃₃ described in “Description of Each Substituent.”

Similarly, a substituted silyl group Sub₅ means at least one group of an alkylsilyl group Sub₅₁ or an arylsilyl group Sub₅₂.

Similarly, a substituted amino group Sub₁₁ means at least one group of an arylamino group Sub₁₁₁ or an alkylamino group Sub₁₁₂.

Herein, a substituent for a “substituted or unsubstituted” group is exemplified by a substituent R_{F1}. The substituent R_{F1} is at least one group selected from the group consisting of an aryl group Sub₁, heteroaryl group Sub₂, alkyl group Sub₃, alkyl halide group Sub₄, substituted silyl group Sub₅, alkylsulfonyl group Sub₆, aralkyl group Sub₇, alkoxy group Sub₈, alkoxy halide group Sub₉, arylalkoxy group Sub₁₀, substituted amino group Sub₁₁, alkenyl group Sub₁₂, cycloalkenyl group Sub₁₂₂, alkynyl group Sub₁₃, alkylthio group Sub₁₄, arylthio group Sub₁₅, substituted phosphino group Sub₁₆, arylcarbonyl group Sub₁₇, acyl group Sub₁₈, substituted phosphoryl group Sub₁₉, ester group Sub₂₀, siloxanyl group Sub₂₁, carbamoyl group Sub₂₂, unsubstituted amino group, unsubstituted silyl group, halogen atom, cyano group, hydroxy group, nitro group, carboxy group, thiol group, and formyl group.

Herein, the substituent R_{F1} for a “substituted or unsubstituted” group may be a diaryl boron group (Ar_{B1}Ar_{B2}B—). Ar_{B1} and Ar_{B2} are exemplified by the above-described aryl group Sub₁. Ar_{B1} and Ar_{B2} in Ar_{B1}Ar_{B2}B— are mutually the same or different.

Specific examples and preferable examples of the substituent R_{F1} are the same as those of the substituents described in “Description of Each Substituent” (e.g., an aryl group Sub₁, heteroaryl group Sub₂, alkyl group Sub₃, alkyl halide group Sub₄, substituted silyl group Sub₅, alkylsulfonyl group Sub₆, aralkyl group Sub₇, alkoxy group Sub₈, alkoxy halide group Sub₉, arylalkoxy group Sub₁₀, substituted amino group Sub₁₁, alkenyl group Sub₁₂, cycloalkenyl group Sub₁₂₂, alkynyl group Sub₁₃, alkylthio group Sub₁₄, arylthio group Sub₁₅, substituted phosphino group Sub₁₆, arylcarbonyl group Sub₁₇, acyl group Sub₁₈, substituted phosphoryl group Sub₁₉, ester group Sub₂₀, siloxanyl group Sub₂₁, and carbamoyl group Sub₂₂).

The substituent R_{F1} for a “substituted or unsubstituted” group may be further substituted by at least one group (hereinafter, also referred to as a substituent R_{F2}) selected from the group consisting of an aryl group Sub₁, heteroaryl group Sub₂, alkyl group Sub₃, alkyl halide group Sub₄, substituted silyl group Sub₅, alkylsulfonyl group Sub₆, aralkyl group Sub₇, alkoxy group Sub₈, alkoxy halide group Sub₉, arylalkoxy group Sub₁₀, substituted amino group Sub₁₁, alkenyl group Sub₁₂, cycloalkenyl group Sub₁₂₂, alkynyl group Sub₁₃, alkylthio group Sub₁₄, arylthio group Sub₁₅, substituted phosphino group Sub₁₆, arylcarbonyl group Sub₁₇, acyl group Sub₁₈, substituted phosphoryl group Sub₁₉, ester group Sub₂₀, siloxanyl group Sub₂₁, carbamoyl group Sub₂₂, unsubstituted amino group, unsubstituted silyl group, halogen atom, cyano group, hydroxy group, nitro group, and carboxy group. Moreover, a plurality of substituents R_{F2} may be bonded to each other to form a ring.

“Unsubstituted” for a “substituted or unsubstituted” group means that a group is not substituted by the above-described substituent R_{F1} but bonded with a hydrogen atom.

Herein, “XX to YY carbon atoms” in the description of “substituted or unsubstituted ZZ group having XX to YY carbon atoms” represent carbon atoms of an unsubstituted ZZ group and do not include carbon atoms of the substituent R_{F1} of the substituted ZZ group.

Herein, “XX to YY atoms” in the description of “substituted or unsubstituted ZZ group having XX to YY atoms” represent atoms of an unsubstituted ZZ group and do not include atoms of the substituent R_{F1} of the substituted ZZ group.

The same description as the above applies to “substituted or unsubstituted” in compounds or partial structures thereof described herein.

Herein, when the substituents are bonded to each other to form a ring, the ring is structured to be a saturated ring, an unsaturated ring, an aromatic hydrocarbon ring or a hetero ring.

Herein, examples of the aromatic hydrocarbon group in the linking group include a divalent or multivalent group obtained by eliminating one or more atoms from the above monovalent aryl group Sub₁.

Herein, examples of the heterocyclic group in the linking group include a divalent or multivalent group obtained by eliminating one or more atoms from the above monovalent heteroaryl group Sub₂.

### EXAMPLES

Example(s) of the invention will be described below. The invention, however, is not limited to Example(s).

### Compounds

The compound represented by the formula (1), the compound represented by the formula (2), and the compound represented by the formula (3) used for producing the organic EL devices in Examples are shown below.

### Compound Represented by Formula (1)

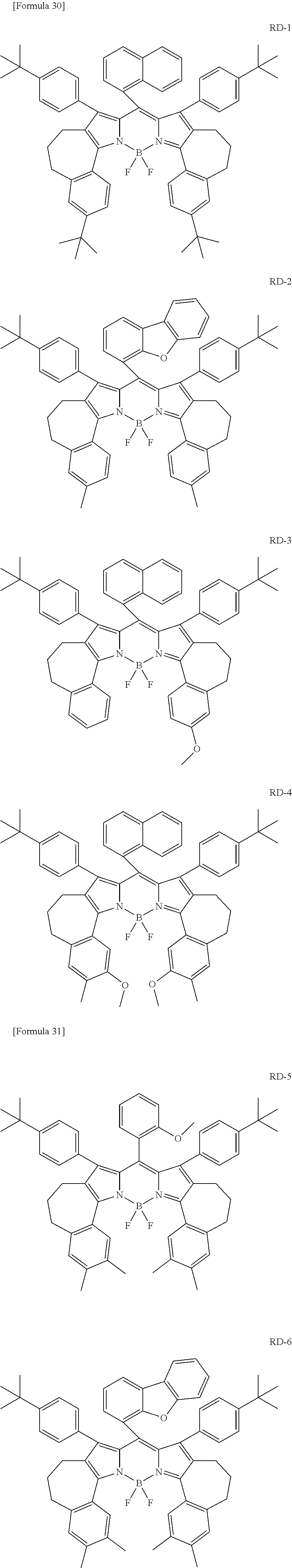

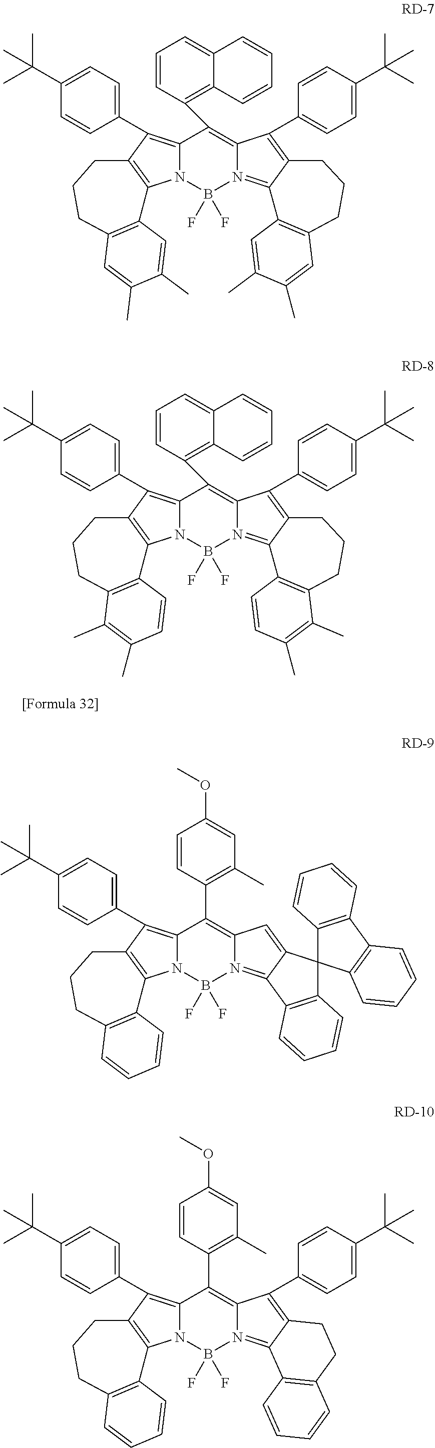

### Compound Represented by Formula (2)

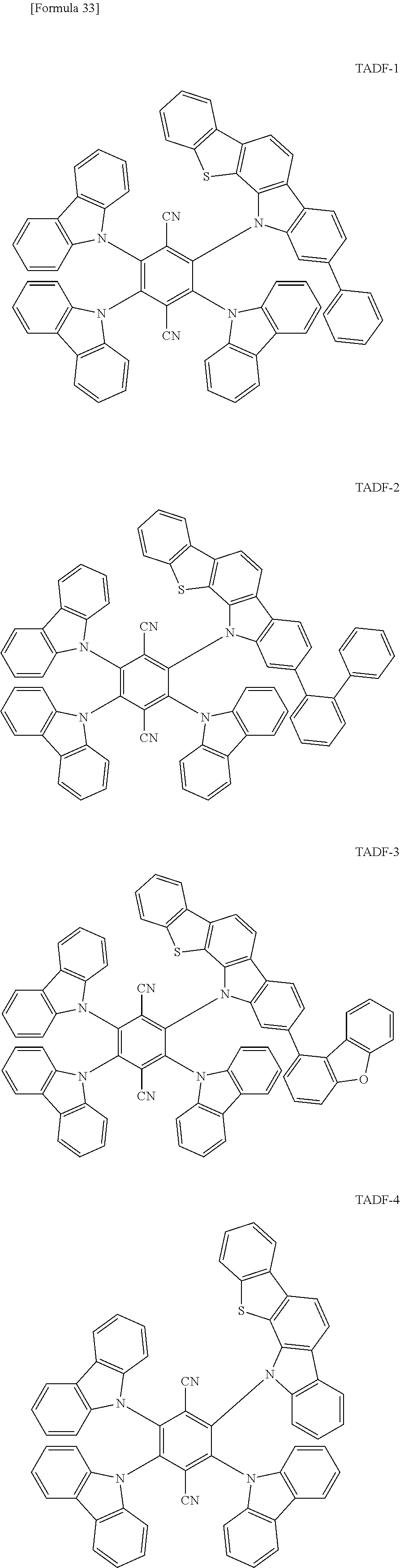

### Compound Represented by Formula (3)

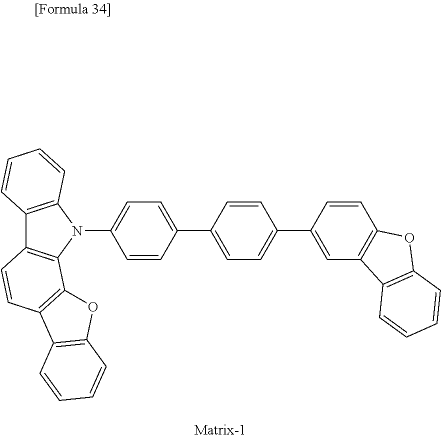 [SMILES: c1ccc2c(c1)oc1ccc(-c3ccc(-c4ccc(-n5c6ccccc6c6ccc7c8ccccc8oc7c65)cc4)cc3)cc12]

Structures of other compounds used for producing the organic EL devices in Comparatives are shown below.

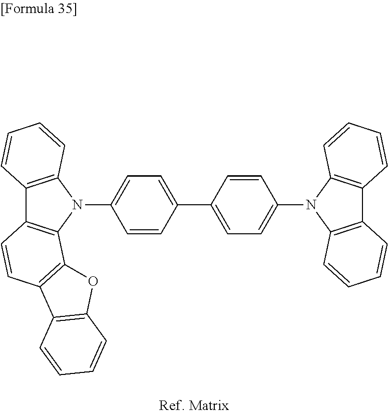 [SMILES: c1ccc2c(c1)oc1c2ccc2c3ccccc3n(-c3ccc(-c4ccc(-n5c6ccccc6c6ccccc65)cc4)cc3)c21]

Structures of other compounds used for producing the organic EL devices in Examples and Comparatives are shown below.

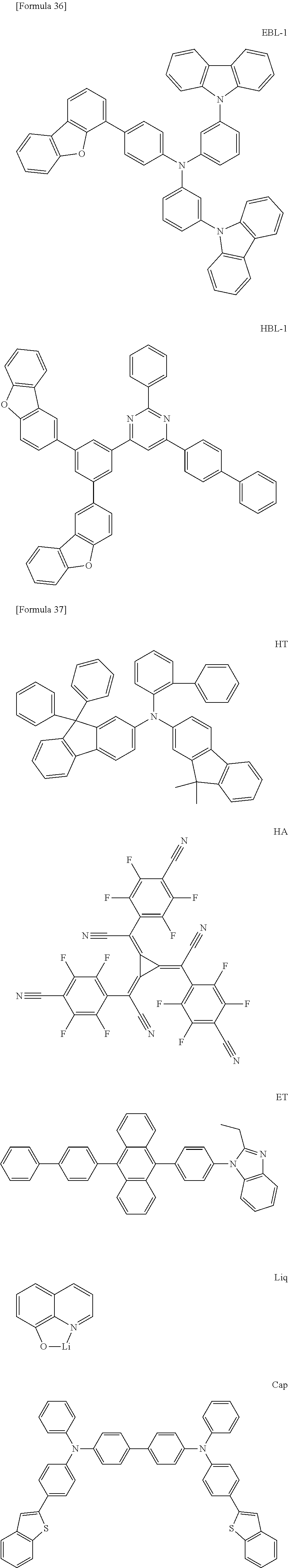

### Production and Evaluation of Organic EL Device Production of Top Emission Type Organic EL Device

### Example 1-1

The organic EL device in Example 1-1 was produced as follows.

An APC (Ag—Pd—Cu) layer (reflective layer) having a film thickness of 100 nm, which was a silver alloy layer, and an indium zinc oxide (IZO) layer having a thickness of 10 nm were sequentially formed by sputtering on a glass substrate. A conductive material layer formed of the APC layer and the IZO layer was thus obtained. IZO is a registered trademark.

Subsequently, with a normal lithography technique, this conductive material layer was patterned by etching using a resist pattern as a mask to form an anode. The substrate formed with the anode as a lower electrode was ultrasonic-cleaned in isopropyl alcohol for five minutes, and then UV-ozone-cleaned for 30 minutes.

Next, a compound HT and a compound HA were co-deposited by vacuum deposition to form a hole injecting layer having a film thickness of 10 nm. The concentrations of the compound HT and the compound HA in the hole injecting layer were 97 mass % and 3 mass %, respectively.

Next, the compound HT was vapor-deposited on the hole injecting layer to form a 185-nm-thick hole transporting layer (HT).

Next, a compound EBL-1 was vapor-deposited on the hole transporting layer to form a 10-nm-thick electron blocking layer as a first layer.

Next, a fluorescent compound RD-1 (the first compound), a delayed fluorescent compound TADF-1 (the second compound), and a compound Matrix-1 (the third compound) were co-deposited on the electron blocking layer to form a 25-nm-thick emitting layer. The concentrations of the compound RD-1, the compound TADF-1, and the compound Matrix-1 in the emitting layer were 1 mass %, 25 mass %, and 74 mass %, respectively.

Next, a compound HBL-1 was vapor-deposited on the emitting layer to form a 15-nm-thick hole blocking layer as a second layer.

Next, a compound ET was vapor-deposited on the hole blocking layer to form a 45-nm-thick electron transporting layer.

Next, lithium fluoride (LiF) was vapor-deposited on the electron transporting layer to form a 1-nm-thick electron injecting electrode (cathode).

Subsequently, Mg and Ag were vapor-deposited at a mass ratio of 15:85 on the electron injectable electrode to form a 15-nm-thick cathode formed of semi-transparent MgAg alloy.

A compound Cap was used to form a film on the cathode by vacuum deposition to form a 65-nm capping layer.

A device arrangement of the organic EL device in Example 1-1 is roughly shown as follows.

APC(100)IZO(10)/HT:HA(10,97%:3%)/HT(185)/EBL-1(10)/Matrix-1:TADF-1:RD-1(25,74%:25%:1%)/HBL-1(15)/ET(45)/LiF(1)/MgAg(15,15%:85)/Cap(65)

Numerals in parentheses represent a film thickness (unit: nm).

The numerals (97%:3%) represented by percentage in the same parentheses indicate a ratio (mass %) between the compound HT and the compound HA in the hole injecting layer. The numerals (74%:25%:1%) represented by percentage in the same parentheses indicate a ratio (mass %) between the third compound, the second compound, and the first compound. The numerals (15%:85%) indicate a ratio (mass %) between Mg and Ag in the cathode. Similar notations apply to the description below.

### Example 1-2 and Example 1-3

The organic EL devices in Example 1-2 and 1-3 were produced in the same manner as in Example 1-1 except that the film thickness of the hole transporting layer of the organic EL device in Example 1-1 was changed as shown in Table 1 below and the first compound in the emitting layer was changed as shown in Table 1.

### Example 1-4

The organic EL device in Example 1-4 was produced as follows.

An APC (Ag—Pd—Cu) layer (reflective layer) having a film thickness of 100 nm, which was a silver alloy layer, and an indium zinc oxide (IZO) layer having a thickness of 10 nm were sequentially formed by sputtering on a glass substrate. A conductive material layer formed of the APC layer and the IZO layer was thus obtained.

Subsequently, with a normal lithography technique, this conductive material layer was patterned by etching using a resist pattern as a mask to form an anode. The substrate formed with the anode as a lower electrode was ultrasonic-cleaned in isopropyl alcohol for five minutes, and then UV-ozone-cleaned for 30 minutes.

Next, the compound HT and the compound HA were co-deposited by vacuum deposition to form a hole injecting layer having a film thickness of 10 nm. The concentrations of the compound HT and the compound HA in the hole injecting layer were 97 mass % and 3 mass %, respectively.

Next, the compound HT was vapor-deposited on the hole injecting layer to form a 175-nm-thick hole transporting layer (HT).

Next, the compound EBL-1 was vapor-deposited on the hole transporting layer to form a 10-nm-thick electron blocking layer as a first layer.

Next, a fluorescent compound RD-4 (the first compound), the delayed fluorescent compound TADF-1 (the second compound), and the compound Matrix-1 (the third compound) were co-deposited on the electron blocking layer to form a 25-nm-thick emitting layer. The concentrations of the compound RD-4, the compound TADF-1, and the compound Matrix-1 in the emitting layer were 1 mass %, 25 mass %, and 74 mass %, respectively.

Next, the compound HBL-1 was vapor-deposited on the emitting layer to form a 15-nm-thick hole blocking layer as a second layer.

Next, the compound ET was vapor-deposited on the hole blocking layer to form a 35-nm-thick first electron transporting layer.

Next, the compound ET and Liq were co-deposited on the first electron transporting layer to form a 20-nm-thick second electron transporting layer. The concentrations of the compound ET and Liq in the second electron transporting layer were 50 mass % and 50 mass %, respectively.

Next, ytterbium (Yb) was vapor-deposited on the second electron transporting layer to form a 1-nm-thick electron injecting electrode (cathode).

Subsequently, Mg and Ag were vapor-deposited at a mass ratio of 10:90 on the electron injectable electrode to form a 15-nm-thick cathode formed of semi-transparent MgAg alloy.

The compound Cap was used to form a film on the cathode by vacuum deposition to form a 65-nm capping layer.

A device arrangement of the organic EL device in Example 1-4 is roughly shown as follows.

AP C(100)IZO(10)/HT:HA(10,97%:3%)/HT(175)/EBL-1(10)/Matrix-1:TADF-1:RD-4(25,74%:25%:1%)/HBL-1(15)/ET(35)/ET:Liq(20,50%:50%)/Yb(1)/MgAg(15,10%:90%)/Cap(65)

### Example 1-5 and Example 1-6

The organic EL devices in Examples 1-5 and 1-6 were produced in the same manner as in Example 1-4 except that the second compound in the emitting layer of the organic EL device in Example 1-4 was changed as shown in Table 2.

### Example 1-7 to Example 1-9

The organic EL devices in Examples 1-7 to 1-9 were produced in the same manner as in Example 1-1 except that the film thickness of the hole transporting layer of the organic EL device in Example 1-1 was changed as shown in Table 3 and the first, second, and third compounds in the emitting layer were changed as shown in Table 3.

### Comparative 1-1 to Comparative 1-3

The organic EL devices in Comparatives 1-1 to 1-3 were produced in the same manner as in Example 1-1 except that the film thickness of the hole transporting layer of the organic EL device in Example 1-1 was changed as shown in Table 3 and the first, second, and third compounds in the emitting layer were changed as shown in Table 3.

### Evaluation of Top Emission Type Organic EL Device

The organic EL devices in Examples 1-1 to 1-9 and Comparatives 1-1 to 1-3 were evaluated as follows. Tables 1 to 3 show the measurement results.

### Drive Voltage

Voltage (unit: V) was measured when current was applied between the anode and the cathode such that a current density was 10 mA/cm².

### Current Efficiency L/J

Voltage was applied to the organic EL device such that a current density was 10 mA/cm², where spectral radiance spectrum was measured by a spectroradiometer CS-2000 (produced by Konica Minolta, Inc.). A current efficiency (unit: cd/A) was calculated based on the obtained spectral radiance spectra, assuming that the spectra was provided under a Lambertian radiation.

### Maximum Peak Wavelength λp and Full Width at Half Maximum FWHM When Device is Driven

Voltage was applied to the organic EL device such that a current density was 10 mA/cm², where spectral radiance spectrum was measured by a spectroradiometer CS-2000 (produced by Konica Minolta, Inc.). A maximum peak wavelength λp (unit: nm) and a full width at half maximum FWHM (unit: nm) were acquired from the obtained spectral radiance spectrum.

### CIE1931 Chromaticity

Voltage was applied to the organic EL device such that a current density was 10 mA/cm², where coordinates (x, y) of CIE1931 chromaticity were measured by a spectroradiometer CS-2000 (produced by Konica Minolta, Inc.).

### Lifetime LT95

Voltage was applied to the produced organic EL device such that a current density was 50 mA/cm², where a time (LT95 (unit: hr)) elapsed before luminance was reduced to 95% of the initial luminance was measured.

TABLE 1

| | | | | Film thickness of | | | | | | |
|---|---|---|---|---|---|---|---|---|---|---|
| | Third | Second | First | hole transporting | Voltage | L/J | λp | FWHM | | LT95 |
| | compound | compound | compound | layer [nm] | [V] | [cd/A] | [nm] | [nm] | CIEx, CIEy | [hr] |
| Ex. 1-1 | Matrix-1 | TADF-1 | RD-1 | 185 | 4.19 | 45.8 | 621 | 35 | (0.679, 0.321) | 283 |
| Ex. 1-2 | Matrix-1 | TADF-1 | RD-2 | 185 | 4.05 | 38.5 | 624 | 36 | (0.684, 0.316) | 251 |
| Ex. 1-3 | Matrix-1 | TADF-1 | RD-3 | 180 | 4.14 | 42.7 | 623 | 34 | (0.683, 0.317) | 274 |

TABLE 2

| | | | | Film thickness of | | | | | | |
|---|---|---|---|---|---|---|---|---|---|---|
| | Third | Second | First | hole transporting | Voltage | L/J | λp | FWHM | | LT95 |
| | compound | compound | compound | layer [nm] | [V] | [cd/A] | [nm] | [nm] | CIEx, CIEy | [hr] |
| Ex. 1-4 | Matrix-1 | TADF-1 | RD-4 | 175 | 4.11 | 44.2 | 622 | 32 | (0.680, 0.319) | 230 |
| Ex. 1-5 | Matrix-1 | TADF-2 | RD-4 | 175 | 4.18 | 49.0 | 623 | 32 | (0.682, 0.316) | 124 |
| Ex. 1-6 | Matrix-1 | TADF-3 | RD-4 | 175 | 4.19 | 47.0 | 625 | 32 | (0.685, 0.314) | 182 |

TABLE 3

| | | | | Film thickness of | | | | | | |
|---|---|---|---|---|---|---|---|---|---|---|
| | Third | Second | First | hole transporting | Voltage | L/J | λp | FWHM | | LT95 |
| | compound | compound | compound | layer [nm] | [V] | [cd/A] | [nm] | [nm] | CIEx, CIEy | [hr] |
| Ex. 1-7 | Matrix-1 | TADF-3 | RD-9 | 170 | 4.32 | 35.3 | 630 | 26 | (0.697, 0.302) | 180 |
| Ex. 1-8 | Matrix-1 | TADF-3 | RD-10 | 170 | 4.31 | 40.6 | 627 | 28 | (0.692, 0.307) | 200 |
| Ex. 1-9 | Matrix-1 | TADF-4 | RD-4 | 175 | 4.38 | 43.0 | 621 | 33 | (0.676, 0.324) | 101 |
| Comp. | ref. Matrix | TADF-3 | RD-9 | 170 | 4.66 | 32.5 | 627 | 26 | (0.689, 0.311) | 68 |
| 1-1 | | | | | | | | | | |
| Comp. | ref. Matrix | TADF-3 | RD-10 | 170 | 4.59 | 39.9 | 625 | 29 | (0.685, 0.314) | 65 |
| 1-2 | | | | | | | | | | |
| Comp. | ref. Matrix | TADF-4 | RD-4 | 175 | 4.56 | 45.7 | 621 | 32 | (0.676, 0.323) | 38 |
| 1-3 | | | | | | | | | | |

The organic EL devices in Examples 1-1 to 1-9 had a lower drive voltage and a longer lifetime than the organic EL devices in Comparatives 1-1 to 1-3.

The organic EL devices in Examples 1-4 to 1-6 had an even lower drive voltage and an even longer lifetime than the organic EL device in Example 1-9, and the organic EL devices in Examples 1-4 to 1-6 had a high luminous efficiency.

### Production of Bottom Emission Type Organic EL Device

### Example 2-1

The organic EL device in Example 2-1 was produced as follows.

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for one minute. The film thickness of ITO was 130 nm.

After the glass substrate having the transparent electrode line was cleaned, the glass substrate was mounted on a substrate holder of a vacuum deposition apparatus. Firstly, the compound HT and the compound HA were co-deposited on a surface of the glass substrate where the transparent electrode line was provided in a manner to cover the transparent electrode, thereby forming a 10-nm-thick hole injecting layer. The concentrations of the compound HT and the compound HA in the hole injecting layer were 97 mass % and 3 mass %, respectively.

Next, the compound HT was vapor-deposited on the hole injecting layer to form a 200-nm-thick hole transporting layer.

Next, the compound EBL-1 was vapor-deposited on the hole transporting layer to form a 10-nm-thick electron blocking layer as a first layer.

Next, the fluorescent compound RD-1 (the first compound), the delayed fluorescent compound TADF-1 (the second compound), and the compound Matrix-1 (the third compound) were co-deposited on the electron blocking layer to form a 25-nm-thick emitting layer. The concentrations of the compound RD-1, the compound TADF-1, and the compound Matrix-1 in the emitting layer were 1 mass %, 25 mass %, and 74 mass %, respectively.

Next, the compound HBL-1 was vapor-deposited on the emitting layer to form a 10-nm-thick hole blocking layer as a second layer.

Next, the compound ET was vapor-deposited on the hole blocking layer to form a 30-nm-thick electron transporting layer.

Next, lithium fluoride (LiF) was vapor-deposited on the electron transporting layer to form a 1-nm-thick electron injecting electrode (cathode).

Subsequently, metal aluminum (Al) was vapor-deposited on the electron injectable electrode to form an 80-nm-thick metal Al cathode.

A device arrangement of the organic EL device in Example 2-1 is roughly shown as follows.

ITO(130)/HT:HA(10,97%:3%)/HT(200)/EBL-1(10)/Matrix-1:TADF-1:RD-1(25,74%:25%:1%)/HBL-1(10)/ET(30)/LiF(1)/Al(80)

Numerals in parentheses represent a film thickness (unit: nm).

### Example 2-2 to Example 2-13

The organic EL devices in Examples 2-2 to 2-13 were produced in the same manner as in Example 2-1 except that the first, second, and third compounds in the emitting layer of the organic EL device in Example 2-1 were changed as shown in Tables 4 to 7.

### Comparative 2-1 to Comparative 2-9

The organic EL devices in Comparatives 2-1 to 2-9 were produced in the same manner as in Example 2-1 except that the first, second, and third compounds in the emitting layer of the organic EL device in Example 2-1 were changed as shown in Tables 4 to 7.

### Evaluation of Bottom Emission Type Organic EL Device

The organic EL devices in Examples 2-1 to 2-13 and Comparatives 2-1 to 2-9 were evaluated as follows. Tables 4 to 7 show the measurement results. Any other evaluation method than the external quantum efficiency EQE is similar to the evaluation method for the top emission type organic EL device.

### External Quantum Efficiency EQE

Voltage was applied to the organic EL device such that a current density was 10 mA/cm², where spectral radiance spectrum was measured by a spectroradiometer CS-2000 (produced by Konica Minolta, Inc.). The external quantum efficiency EQE (unit: %) was calculated based on the obtained spectral radiance spectra, assuming that the spectra was provided under a Lambertian radiation.

TABLE 4

| | | | | | | | Full width at half | | |
|---|---|---|---|---|---|---|---|---|---|
| | Third | Second | First | Voltage | EQE | λp | maximum FWHM | | LT95 |
| | compound | compound | compound | [V] | [%] | [nm] | [nm] | CIEx, CIEy | [hr] |
| Ex. | Matrix-1 | TADF-1 | RD-1 | 4.16 | 16.4 | 616 | 39 | (0.659, 0.340) | 245 |
| 2-1 | | | | | | | | | |
| Ex. | Matrix-1 | TADF-1 | RD-5 | 4.21 | 14.7 | 618 | 40 | (0.662, 0.338) | 197 |
| 2-2 | | | | | | | | | |
| Ex. | Matrix-1 | TADF-1 | RD-2 | 4.02 | 15.9 | 621 | 40 | (0.669, 0.331) | 267 |
| 2-3 | | | | | | | | | |
| Ex. | Matrix-1 | TADF-1 | RD-6 | 4.12 | 15.7 | 624 | 40 | (0.670, 0.330) | 228 |
| 2-4 | | | | | | | | | |
| Ex. | Matrix-1 | TADF-1 | RD-7 | 4.15 | 15.3 | 619 | 39 | (0.668, 0.332) | 220 |
| 2-5 | | | | | | | | | |
| Ex. | Matrix-1 | TADF-1 | RD-8 | 4.10 | 15.2 | 619 | 39 | (0.667, 0.333) | 199 |
| 2-6 | | | | | | | | | |
| Ex. | Matrix-1 | TADF-1 | RD-3 | 4.22 | 15.2 | 622 | 39 | (0.670, 0.330) | 312 |
| 2-7 | | | | | | | | | |
| Ex. | Matrix-1 | TADF-1 | RD-4 | 4.10 | 16.7 | 625 | 39 | (0.675, 0.324) | 281 |
| 2-8 | | | | | | | | | |
| Comp. | ref. Matrix | TADF-1 | RD-5 | 4.44 | 14.5 | 619 | 40 | (0.666, 0.333) | 112 |
| 2-1 | | | | | | | | | |
| Comp. | ref. Matrix | TADF-1 | RD-2 | 4.37 | 16.9 | 622 | 40 | (0.669, 0.330) | 100 |
| 2-2 | | | | | | | | | |
| Comp. | ref. Matrix | TADF-1 | RD-6 | 4.38 | 16.3 | 626 | 40 | (0.673, 0.326) | 71 |
| 2-3 | | | | | | | | | |
| Comp. | ref. Matrix | TADF-1 | RD-4 | 4.43 | 17.0 | 626 | 39 | (0.675, 0.325) | 149 |
| 2-4 | | | | | | | | | |

The organic EL devices in Examples 2-1 to 2-8 had a lower drive voltage and a longer lifetime than the organic EL devices in Comparatives 2-1 to 2-4.

TABLE 5

| | | | | | | | Full width at half | | |
|---|---|---|---|---|---|---|---|---|---|
| | Third | Second | First | Voltage | EQE | λp | maximum FWHM | | LT95 |
| | compound | compound | compound | [V] | [%] | [nm] | [nm] | CIEx, CIEy | [hr] |
| Ex. | Matrix-1 | TADF-2 | RD-4 | 4.23 | 18.8 | 625 | 38 | (0.670, 0.329) | 105 |
| 2-9 | | | | | | | | | |
| Comp. | ref. Matrix | TADF-2 | RD-4 | 4.46 | 19.5 | 625 | 38 | (0.673, 0.326) | 60 |
| 2-5 | | | | | | | | | |

The organic EL device in Example 2-9 had a lower drive voltage and a longer lifetime than the organic EL device in Comparative 2-5.

TABLE 6

| | | | | | | | Full width at half | | |
|---|---|---|---|---|---|---|---|---|---|
| | Third | Second | First | Voltage | EQE | λp | maximum FWHM | | LT95 |
| | compound | compound | compound | [V] | [%] | [nm] | [nm] | CIEx, CIEy | [hr] |
| Ex. | Matrix-1 | TADF-3 | RD-4 | 4.26 | 18.4 | 625 | 38 | (0.672, 0.327) | 162 |
| 2-10 | | | | | | | | | |
| Ex. | Matrix-1 | TADF-3 | RD-9 | 4.18 | 14.6 | 630 | 29 | (0.688, 0.310) | 201 |
| 2-11 | | | | | | | | | |
| Ex. | Matrix-1 | TADF-3 | RD-10 | 4.10 | 14.2 | 628 | 33 | (0.687, 0.312) | 160 |
| 2-12 | | | | | | | | | |
| Comp. | ref. Matrix | TADF-3 | RD-4 | 4.51 | 18.7 | 625 | 38 | (0.672, 0.326) | 91 |
| 2-6 | | | | | | | | | |
| Comp. | ref. Matrix | TADF-3 | RD-9 | 4.46 | 17.0 | 629 | 29 | (0.684, 0.315) | 87 |
| 2-7 | | | | | | | | | |
| Comp. | ref. Matrix | TADF-3 | RD-10 | 4.32 | 16.4 | 629 | 34 | (0.685, 0.314) | 80 |
| 2-8 | | | | | | | | | |

The organic EL devices in Examples 2-10 to 2-12 had a lower drive voltage and a longer lifetime than the organic EL devices in Comparatives 2-6 to 2-8.

TABLE 7

| | | | | | | | Full width at half | | |
|---|---|---|---|---|---|---|---|---|---|
| | Third | Second | First | Voltage | EQE | λp | maximum FWHM | | LT95 |
| | compound | compound | compound | [V] | [%] | [nm] | [nm] | CIEx, CIEy | [hr] |
| Ex. | Matrix-1 | TADF-4 | RD-4 | 4.08 | 16.1 | 625 | 38 | (0.676, 0.324) | 103 |
| 2-13 | | | | | | | | | |
| Comp. | ref. Matrix | TADF-4 | RD-4 | 4.28 | 18.0 | 624 | 39 | (0.673, 0.327) | 72 |
| 2-9 | | | | | | | | | |

The organic EL device in Example 2-13 had a lower drive voltage and a longer lifetime than the organic EL device in Comparative 2-9.

The organic EL devices in Examples 2-8 to 2-10 had an even lower drive voltage and an even longer lifetime than the organic EL device in Example 2-13, and the organic EL devices in Examples 2-8 to 2-10 had a high luminous efficiency.

Table 8 shows physical properties of the first, second, third compounds used in Examples.

TABLE 8

| | | S₁ [eV] | ΔST [eV] | λ[nm] |
|---|---|---|---|---|
| First compound | RD-1 | 2.01 | — | 615 |
| | RD-2 | 2.00 | — | 618 |
| | RD-3 | 2.00 | — | 617 |
| | RD-4 | 1.99 | — | 621 |
| | RD-5 | 2.01 | — | 616 |
| | RD-6 | 1.99 | — | 620 |
| | RD-7 | 2.01 | — | 616 |
| | RD-8 | 2.01 | — | 616 |
| | RD-9 | 1.97 | — | 628 |
| | RD-10 | 1.98 | — | 625 |
| Second | TADF-1 | 2.34 | <0.01 | 539 |
| compound | TADF-2 | 2.34 | <0.01 | 539 |
| | TADF-3 | 2.34 | <0.01 | 538 |
| | TADF-4 | 2.34 | <0.01 | 539 |
| Third | Matrix-1 | 3.41 | — | — |
| compound | | | | |
| Comparative | ref. Matrix | 3.42 | — | — |
| compound | | | | |

Explanation of Tables
“—” represents that no measurement was performed.
“<0.01” represents that ΔST is less than 0.01 eV.

### Evaluation of Compounds

Physical properties of compounds shown in Table 8 were measured according to the following methods.

### Delayed Fluorescence of Compounds

Delayed fluorescence was checked by measuring transient PL using an apparatus depicted in FIG. 2. The compound TADF-1 was dissolved in toluene to prepare a dilute solution with an absorbance of 0.05 or less at the excitation wavelength to eliminate contribution of self-absorption. In order to prevent quenching due to oxygen, the sample solution was frozen and degassed and then sealed in a cell with a lid under an argon atmosphere to obtain an oxygen-free sample solution saturated with argon.

The fluorescence spectrum of the sample solution was measured with a spectrofluorometer FP-8600 (produced by JASCO Corporation), and the fluorescence spectrum of a 9,10-diphenylanthracene ethanol solution was measured under the same conditions. Using the fluorescence area intensities of both spectra, the total fluorescence quantum yield was calculated by an equation (1) in Morris et al. J. Phys. Chem. 80 (1976) 969.

Prompt emission was observed immediately when the excited state was achieved by exciting the compound TADF-1 with a pulse beam (i.e., a beam emitted from a pulse laser) having a wavelength to be absorbed by the compound TADF-1, and Delay emission was observed not immediately when the excited state was achieved but after the excited state was achieved. The delayed fluorescence in Examples means that an amount of Delay emission is 5% or more with respect to an amount of Prompt emission. Specifically, provided that the amount of Prompt emission is denoted by X_{P} and the amount of Delay emission is denoted by X_{D}, the delayed fluorescence means that a value of X_{D}/X_{P} is 0.05 or more.

An amount of Prompt emission, an amount of Delay emission and a ratio between the amounts thereof can be obtained according to the method as described in “Nature 492, 234-238, 2012” (Reference Document 1). The amount of Prompt emission and the amount of Delay emission may be calculated using an apparatus different from one described in Reference Document 1 or one depicted in FIG. 2.

Measurement for compounds TADF-2, TADF-3, and TADF-4 was performed as in the compound TADF-1.

It was confirmed that the amount of Delay emission was 5% or more with respect to the amount of Prompt emission in the compounds TADF-1, TADF-2, TADF-3, and TADF-4. Specifically, the value of X_{D}/X_{P} was 0.05 or more in the compounds TADF-1, TADF-2, TADF-3, and TADF-4.

### Singlet Energy S₁

The singlet energy S₁ was measured according to the above-described solution method.

### ΔST

ΔST was calculated based on the measurement results of the energy gap T_{77K} at 77K of the compounds TADF-1, TADF-2, TADF-3, and TADF-4 and the values of the above singlet energy S₁. The energy gap T_{77K} was measured by the measurement method of the energy gap T_{77K} described in the above “Relationship between Triplet Energy and Energy Gap at 77K.”

### Maximum Peak Wavelength λ of Compounds

A maximum peak wavelength λ of the compound was measured according to the following method.

A toluene solution of a measurement target compound at a concentration of 5 μmol/L was prepared and put in a quartz cell. An emission spectrum (ordinate axis: luminous intensity, abscissa axis: wavelength) of the thus-obtained sample was measured at a normal temperature (300K). In Examples, an emission spectrum was measured with a spectrophotofluorometer (manufactured by Hitachi High-Tech Science Corporation: F-7000). It should be noted that the machine for measuring the emission spectrum is not limited to the machine used herein. A peak wavelength of the emission spectrum exhibiting the maximum luminous intensity was defined as a maximum peak wavelength λ.

### Synthesis of Compounds

### Synthesis Example 1

A synthesis method of the compound TADF-2 will be described below.

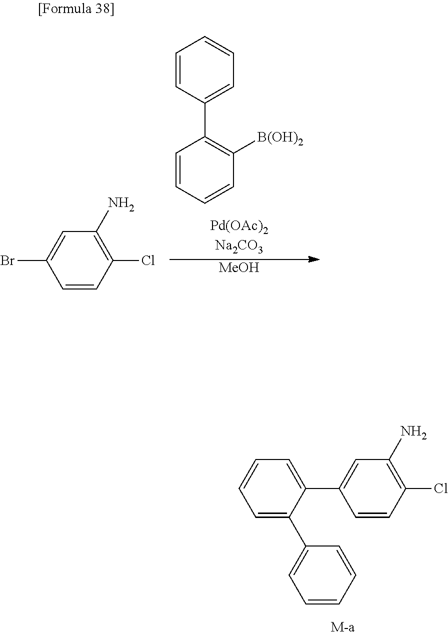 [SMILES: "MeOH" ; Nc1cc(Br)ccc1Cl ; OB(O)c1ccccc1-c1ccccc1 ; Nc1cc(-c2ccccc2-c2ccccc2)ccc1Cl]

Under nitrogen atmosphere, 5-bromo-2-chloro-aniline (10 g, 49 mmol), 2-biphenyl boronate (9.7 g, 49 mmol), palladium acetate (0.11 g, 0.5 mmol), sodium carbonate (10 g, 98 mmol), and methanol (100 mL) were put into a 300-mL three-neck flask and were stirred at 80 degrees C. for six hours. Ion exchange water (100 mL) was added to the reaction mixture. Then, the deposited solid was purified by silica-gel column chromatography to obtain a white solid (13.3 g). Through Gas Chromatograph Mass Spectometer (GC-MS) analysis, the white solid was identified as a compound M-a (yield 97%).

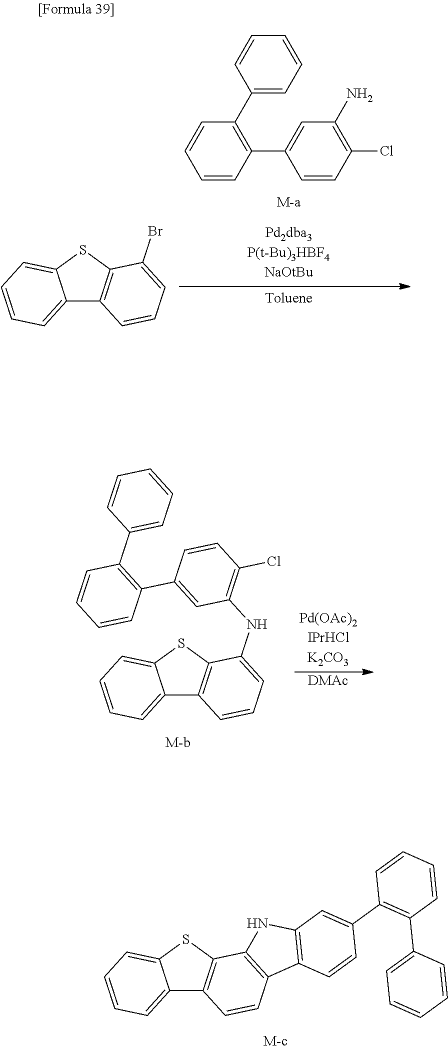

Under nitrogen atmosphere, 4-bromodibenzothiophene (10 g, 38 mmol), the compound M-a (11 g, 38 mmol), tris(dibenzylidene acetone)dipalladium(0) (Pd₂dba₃) (0.35 g, 0.38 mmol), tri-tert-butylphosphonium tetrafluoroborate (P(t-Bu)₃HBF₄) (0.44 g, 1.5 mmol), sodium tert-butoxide (NaOtBu) (5.5 g, 57 mmol), and toluene (120 mL), which were put into a 200-mL three-neck flask, were heated and stirred at 60 degrees C. for four hours and then cooled to a room temperature (25 degrees C.). The reaction solution was purified by silica-gel column chromatography to obtain a white solid (16 g). Through GC-MS analysis, the white solid was identified as a compound M-b (yield 91%).

Under nitrogen atmosphere, the compound M-b (16 g, 35 mmol), 1,3-bis(2,6-diisopropylphenyl)imidazoliumchloride (IPrHCl) (0.30 g, 0.70 mmol), palladium(II) acetate (Pd(OAc)2) (78 mg, 0.35 mmol), potassium carbonate (9.7 g, 70 mmol), and N,N-dimethylacetamide (DMAc) (100 mL) were put into a 200-mL three-neck flask, stirred at 160 degrees C. for three hours, and then cooled to a room temperature (25 degrees C.). The reaction solution was purified by silica-gel column chromatography to obtain a white solid (10.6 g). Through GC-MS analysis, the white solid was identified as a compound M-c (yield 72%).

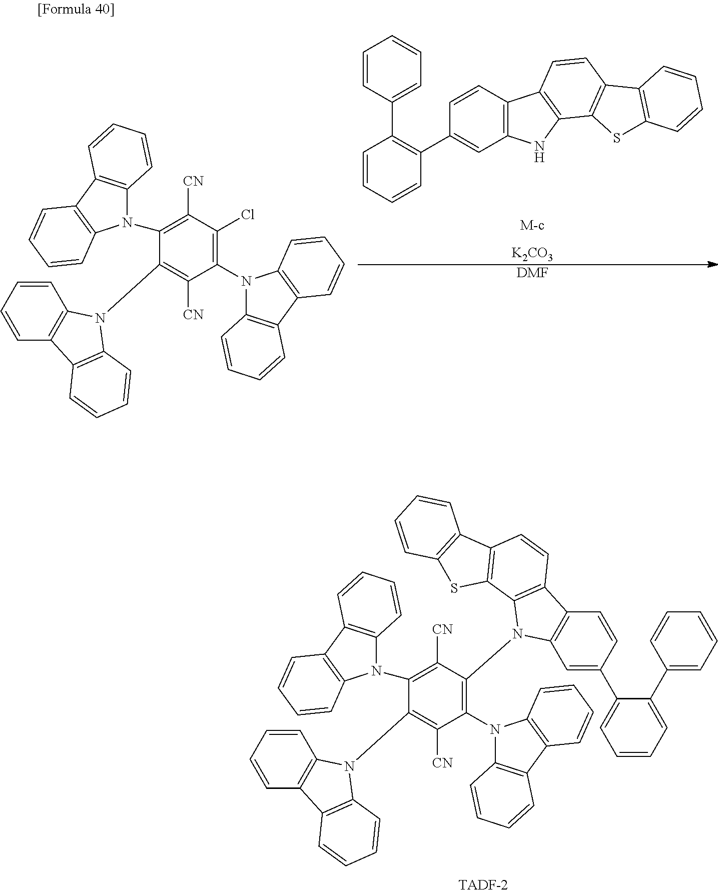

Under nitrogen atmosphere, 1,4-benzene dicarbonitrile,2,3,5-tri-9H-carbazole-9-yl-6-chloro (3.0 g, 4.6 mmol), the compound M-c (2.4 g, 5.5 mmol), potassium carbonate (1.1 g, 8.2 mmol), and N,N-dimethylformamide (DMF) (20 mL) were put into a 50-mL three-neck flask and were stirred at 120 degrees C. for four hours. Saturated ammonium chloride aqueous solution (10 mL) was added to the reaction mixture. Then, the deposited solid was purified by silica-gel column chromatography to obtain a red solid (4.2 g). Through Atmospheric Pressure Solid Analysis Probe Mass Spectrometry (ASAP-MS) analysis, the red solid was identified as TADF-2 (yield 88%).

### Synthesis Example 2

A synthesis method of the compound TADF-3 will be described below.

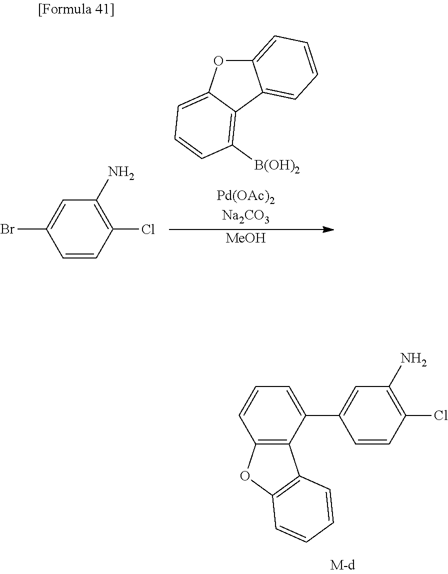 [SMILES: "MeOH" ; OB(O)c1cccc2oc3ccccc3c12 ; Nc1cc(Br)ccc1Cl ; Nc1cc(-c2cccc3oc4ccccc4c23)ccc1Cl]

Under nitrogen atmosphere, 5-bromo-2-chloro-aniline (10 g, 49 mmol), 1-dibenzofuranyl boronate (10.4 g, 49 mmol), palladium acetate (0.11 g, 0.5 mmol), sodium carbonate (10 g, 98 mmol), and methanol (100 mL) were put into a 300-mL three-neck flask and stirred at 80 degrees C. for eight hours. Ion exchange water (100 mL) was added to the reaction mixture. Then, the deposited solid was purified by silica-gel column chromatography to obtain a white solid (13.7 g). Through GC-MS analysis, the white solid was identified as a compound M-d (yield 95%).

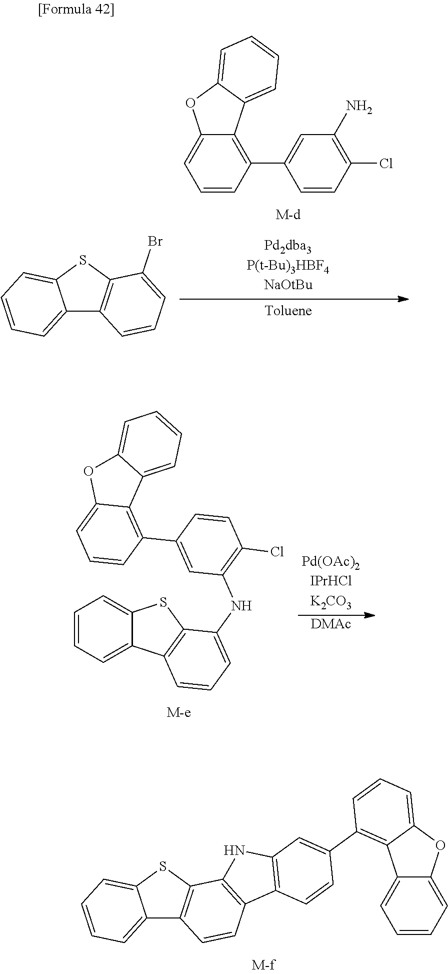

Under nitrogen atmosphere, 4-bromodibenzothiophene (10 g, 38 mmol), the compound M-d (11.2 g, 38 mmol), tris(dibenzylidene acetone)dipalladium(0) (Pd₂dba₃) (0.35 g, 0.38 mmol), tri-tert-butylphosphonium tetrafluoroborate (P(t-Bu)₃HBF₄) (0.44 g, 1.5 mmol), sodium tert-butoxide (NaOtBu) (5.5 g, 57 mmol), and toluene (120 mL), which were put into a 200-mL three-neck flask, were heated and stirred at 60 degrees C. for four hours and then cooled to a room temperature (25 degrees C.). The reaction solution was purified by silica-gel column chromatography to obtain a white solid (17.7 g). Through GC-MS analysis, the white solid was identified as a compound M-e (yield 98%).

Under nitrogen atmosphere, the compound M-e (17.7 g, 37.2 mmol), 1,3-bis(2,6-diisopropylphenyl)imidazoliumchloride (IPrHCl) (0.32 g, 0.74 mmol), palladium(II) acetate (Pd(OAc)2) (84 mg, 0.37 mmol), potassium carbonate (10.2 g, 74 mmol), and N,N-dimethylacetamide (DMAc) (100 mL) were put into a 200-mL three-neck flask, stirred at 160 degrees C. for three hours, and then cooled to a room temperature (25 degrees C.). The reaction solution was purified by silica-gel column chromatography to obtain a white solid (14.4 g). Through GC-MS analysis, the white solid was identified as a compound M-f (yield 88%).

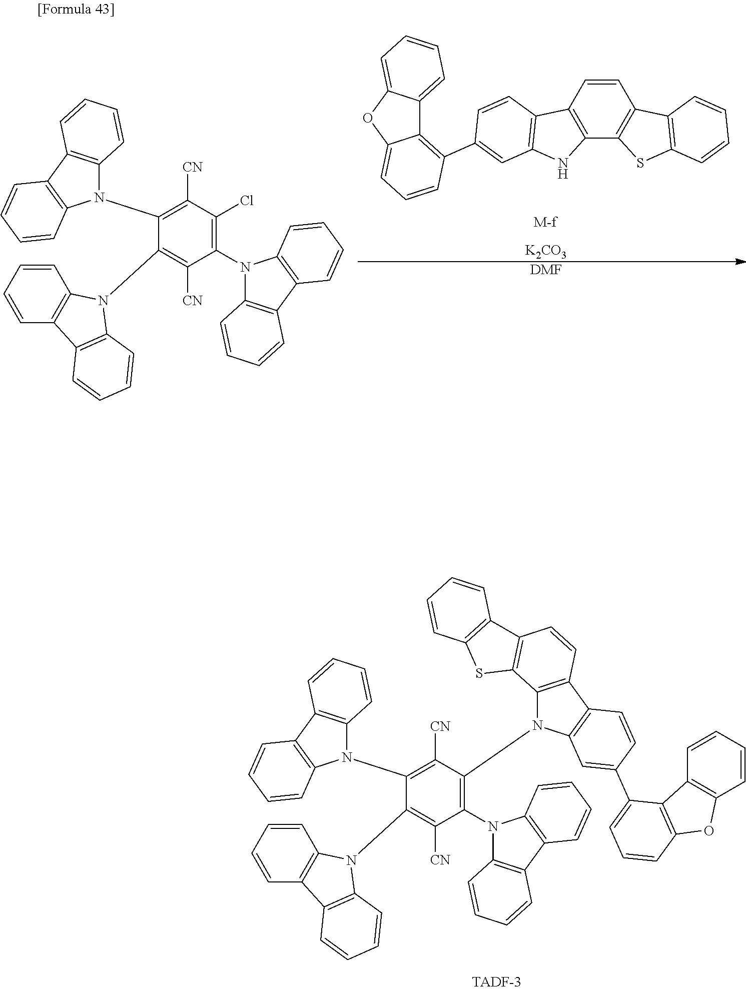

Under nitrogen atmosphere, 1,4-benzene dicarbonitrile, 2,3,5-tri-9H-carbazole-9-yl-6-chloro (3.0 g, 4.6 mmol), the compound M-f (2.4 g, 5.5 mmol), potassium carbonate (1.1 g, 8.2 mmol), and DMF (20 mL) were put into a 50-mL three-neck flask and were stirred at 120 degrees C. for four hours. Saturated ammonium chloride aqueous solution (10 mL) was added to the reaction mixture. Then, the deposited solid was purified by silica-gel column chromatography to obtain a red solid (3.5 g). Through ASAP-MS analysis, the red solid was identified as TADF-3 (yield 71%).

### EXPLANATION OF CODES

1 . . . organic EL device, 3 . . . anode, 4 . . . cathode, 5 . . . emitting layer, 7 . . . hole transporting layer, 8 . . . electron transporting layer

1. An organic electroluminescence device comprising:
an anode;
a cathode; and
an emitting layer provided between the anode and the cathode, wherein
the emitting layer comprises a first compound that fluoresces, a second compound that exhibits delayed fluorescence, and a third compound,
wherein the first compound is of formula (1): 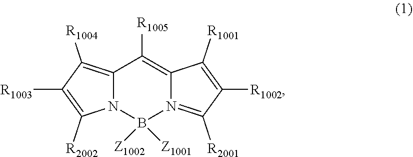
wherein, in formula (1)
R₁₀₀₁ to R₁₀₀₅ and R₂₀₀₁ to R₂₀₀₂ are independently H or a substituent, or at least one combination of a combination of R₁₀₀₁ and R₁₀₀₂, a combination of R₁₀₀₂ and R₂₀₀₁ a combination of R₂₀₀₂ and R₁₀₀₃, or a combination of R₁₀₀₃ and R₁₀₀₄ are mutually bonded to form a ring,
R₁₀₀₁ to R₁₀₀₅ and R₂₀₀₁ to R₂₀₀₂ as the substituents are independently a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted cycloalkenyl group having 3 to 30 ring carbon atoms, a substituted or unsubstituted alkynyl group having 2 to 30 carbon atoms, a substituted or unsubstituted heteroaryl group having 5 to 30 ring atoms, a halogen atom, a carboxy group, a formyl group, a substituted or unsubstituted acyl group, a substituted or unsubstituted ester group, a substituted or unsubstituted carbamoyl group, a substituted or unsubstituted amino group, a hydroxy group, a thiol group, a nitro group, a cyano group, a substituted or unsubstituted silyl group, and a substituted or unsubstituted siloxanyl group, and
Z₁₀₀₁ and Z₁₀₀₂ are independently a halogen atom, a cyano group, a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted alkoxy group having 1 to 30 carbon atoms, a substituted or unsubstituted alkoxy halide group having 1 to 30 carbon atoms, and a substituted or unsubstituted aryloxy group having 6 to 30 ring carbon atoms,
wherein the second compound is of formula (2): 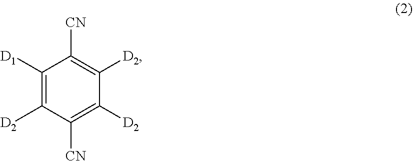
wherein, in formula (2),
CN is a cyano group,
D₁ is a group of formula (2-1): 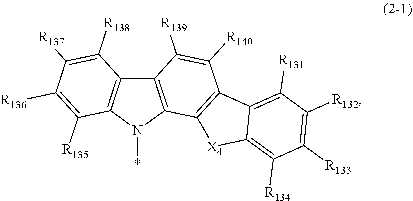
wherein, in formula (2-1),
X₄ is S,
R₁₃₁ to R₁₄₀ are independently H or a substituent, which is independently a substituted or unsubstituted aryl group having 6 to 14 ring carbon atoms, a substituted or unsubstituted heterocyclic group having 5 to 14 ring atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms, and
* is a bonding position to a benzene ring in the formula (2),
D₂ is a group of formula (2-2), a plurality of D₂ being mutually the same group: 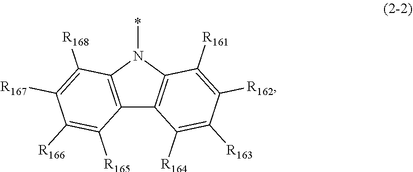
wherein, in the formula (2-2),
R₁₆₁ to R₁₆₈ are each independently H or a substituent, which is independently a halogen atom, a substituted or unsubstituted aryl group having 6 to 14 ring carbon atoms, a substituted or unsubstituted heterocyclic group having 5 to 14 ring atoms, a substituted or unsubstituted alkyl group having 1 to 6 carbon atoms, a substituted or unsubstituted cycloalkyl group having 3 to 30 ring carbon atoms, a substituted or unsubstituted alkyl halide group having 1 to 30 carbon atoms, a substituted or unsubstituted alkylsilyl group having 3 to 6 carbon atoms, a substituted or unsubstituted alkoxy group having 1 to 6 carbon atoms, a substituted or unsubstituted aryloxy group having 6 to 14 ring carbon atoms, a substituted or unsubstituted alkylamino group having 2 to 12 carbon atoms, a substituted or unsubstituted alkylthio group having 1 to 6 carbon atoms, or a substituted or unsubstituted arylthio group having 6 to 14 ring carbon atoms, and
* is independently a bonding position to a benzene ring in the formula (2),
wherein the third compound is of formula (3): 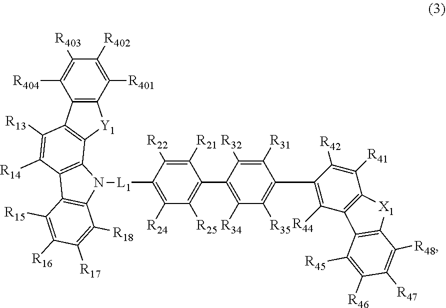
wherein, in the formula (3):
X₁ is an oxygen atom or a sulfur atom;
Y₁ is an oxygen atom or a sulfur atom,
L₁ is a single bond or a linking group;
L₁ as the linking group is a group derived from a substituted or unsubstituted aryl group having 6 to 30 ring carbon atoms, a group derived from a substituted or unsubstituted heterocyclic group having 5 to 30 ring atoms, or a group formed by bonding two groups selected from the group consisting of a group derived from a substituted or unsubstituted aryl group having 6 to 30 ring carbon atoms and a group derived from a substituted or unsubstituted heterocyclic group having 5 to 30 ring atoms;
R₄₁, R₄₂ and R₄₄ to R₄₈ are each independently a hydrogen atom or a substituent, or at least one combination of a combination of R₄₁ and R₄₂, a combination of R₄₅ and R₄₆, a combination of R₄₆ and R₄₇, or a combination of R₄₇ and R₄₈ are mutually bonded to form a ring;
R₁₃ to R₁₈, R₂₁, R₂₂, R₂₄, R₂₅, R₃₁, R₃₂, R₃₄, R₃₅, and R₄₀₁ to R₄₀₄ are independently H or a substituent, or at least one combination of a combination of R₁₃ and R₁₄, a combination of R₁₅ and R₁₆, a combination of R₁₆ and R₁₇, a combination of R₁₇ and R₁₈, a combination of R₄₀₁ and R₄₀₂, a combination of R₄₀₂ and R₄₀₃, or a combination of R₄₀₃ and R₄₀₄ are mutually bonded to form a ring,
R₁₃ to R₁₈, R₂₁, R₂₂, R₂₄, R₂₅, R₃₁, R₃₂, R₃₄, R₃₅, R₄₁, R₄₂, R₄₄ to R₄₈, and R₄₀₁ to R₄₀₄ as the substituents are independently a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkyl halide group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 60 ring carbon atoms, a substituted or unsubstituted aryl phosphoryl group having 6 to 60 ring carbon atoms, a hydroxy group, a substituted or unsubstituted alkoxy group having 1 to 30 carbon atoms, a substituted or unsubstituted aryloxy group having 6 to 30 ring carbon atoms, an amino group, a substituted or unsubstituted alkylamino group having 2 to 30 carbon atoms, a substituted or unsubstituted arylamino group having 6 to 60 ring carbon atoms, a thiol group, a substituted or unsubstituted alkylthio group having 1 to 30 carbon atoms, or a substituted or unsubstituted arylthio group having 6 to 30 ring carbon atoms, and
wherein a singlet energy of the first compound S₁(M1), a singlet energy of the second compound S₁(M2), and a singlet energy of the third compound S₁(M3) satisfy a relationship of a numerical formula of Inequality,
S₁(M3)>S₁(M2)>S₁(M1) (1)

2. The device of claim 1, wherein R₂₀₀₁ and R₂₀₀₂ in the formula (1) are independently a substituted or unsubstituted aryl group having 6 to 30 ring carbon atoms or a substituted or unsubstituted heteroaryl group having 5 to 30 ring atoms.

3. The device of claim 1, wherein the compound of formula (1) is a of formula (4A) or formula (4B): 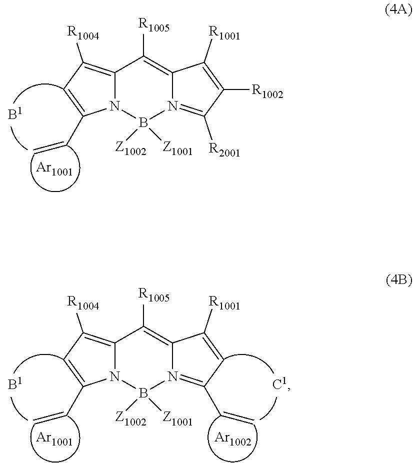
wherein, R₁₀₀₁, R₁₀₀₂, R₁₀₀₄, R₁₀₀₅, R₂₀₀₁, Z₁₀₀₁, and Z₁₀₀₂ are each independently the same as R₁₀₀₁, R₁₀₀₂, R₁₀₀₄, R₁₀₀₅, R₂₀₀₁ , Z₁₀₀₁ , and Z₁₀₀₂ in the formula (1),
Ar₁₀₀₁ and Ar₁₀₀₂ are independently a substituted or unsubstituted aromatic hydrocarbon ring having 6 to 30 ring carbon atoms or a substituted or unsubstituted aromatic heterocycle having 5 to 30 ring atoms,
B¹ is a cross-linking structure in which three or more atoms are bonded in series, the atoms being a substituted or unsubstituted C, a substituted or unsubstituted Si, a substituted or unsubstituted N, a substituted or unsubstituted P, O, or S, and
C¹ is a cross-linking structure in which one or more atoms are bonded in series, the atoms being a substituted or unsubstituted C, a substituted or unsubstituted Si, a substituted or unsubstituted N, a substituted or unsubstituted P, O, and S, and
wherein, when B¹ is a trimethylene group, R₁₀₀₄ is neither H nor a halogen atom.

4. The device of claim 3, wherein B¹ is a cross-linking structure of formula (5A) or formula (5B): 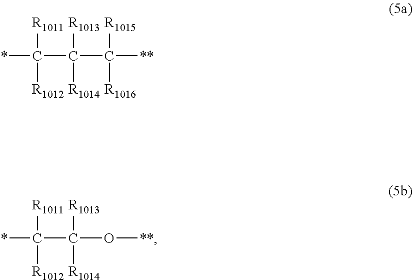
wherein,
R₁₀₁₁ to R₁₀₁₆ are independently H or a substituent, or at least one combination of combinations of adjacent two or more of R₁₀₁₁ to R₁₀₁₆ are mutually bonded to form a ring,
R₁₀₁₁ to R₁₀₁₆ as the substituents are independently a substituted or unsubstituted alkyl group having 1 to 30 carbon atoms, a substituted or unsubstituted alkyl halide group having 1 to 30 carbon atoms, a substituted or unsubstituted cycloalkyl group having 3 to 30 ring carbon atoms, a substituted or unsubstituted aryl group having 6 to 30 ring carbon atoms, a substituted or unsubstituted heteroaryl group having 5 to 30 ring atoms, a substituted or unsubstituted alkoxy group having 1 to 30 carbon atoms, a substituted or unsubstituted alkoxy halide group having 1 to 30 carbon atoms, a substituted or unsubstituted alkylthio group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted alkenyl group having 2 to 30 carbon atoms, a substituted or unsubstituted cycloalkenyl group having 3 to 30 ring carbon atoms, a substituted or unsubstituted alkynyl group having 2 to 30 carbon atoms, a halogen atom, a carboxy group, a formyl group, a substituted or unsubstituted acyl group, a substituted or unsubstituted ester group, a substituted or unsubstituted carbamoyl group, a substituted or unsubstituted amino group, a hydroxy group, a thiol group, a nitro group, a cyano group, a substituted or unsubstituted silyl group, or a substituted or unsubstituted siloxanyl group,
* is a bonding site to a pyrrole ring, and
** is a bonding site to Ar₁₀₀₁ in the formulae (4A) and (4B).

5. The device of claim 1, wherein in the formulae (2-1) and (2-2), R₁₃₁ to R₁₄₀ and R₁₆₁ to R₁₆₈ are independently a hydrogen atom, a substituted or unsubstituted aryl group having 6 to 14 ring carbon atoms, or a substituted or unsubstituted heterocyclic group having 5 to 14 ring atoms.

6. The device of claim 1, wherein in the formula (2-1), R₁₃₆ is a substituted or unsubstituted awl group having 6 to 14 ring carbon atoms, or a substituted or unsubstituted heterocyclic group having 5 to 14 ring atoms.

7. The device of claim 1, wherein in the formula (3), X₁ is O.

8. The device of claim 1, wherein in the formula (3), Y₁ is O.

9. The device of claim 1, wherein in the formula (3), L₁ is a single bond or a linking group, and
wherein L₁ as the linking group is a group derived from a substituted or unsubstituted aryl group having 6 to 30 ring carbon atoms.

10. The of claim 1, wherein in the formula (3), R₁₃ to R₁₈, R₂₁, R₂₂, R₂₄, R₂₅, R₃₁, R₃₂, R₃₄, R₃₅, R₄₁, R₄₂, R₄₄ to R₄₈, and R₄₀₁ to R₄₀₄, are independently H or a substituent,
which is independently a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

11. The device of claim 1, wherein the emitting layer comprises no metal complex.

12. The device of claim 1, wherein the emitting layer comprises no heavy metal complex.

13. An electronic device, comprising:
the organic electroluminescence device of claim 1.
